(19) United States
(12) Patent Application Publication
(10) Pub. No.: US 2021/0079270 A1
(43) Pub. Date: Mar. 18, 2021

(54) SHEET BODY, ELECTRONIC PART CASE, METHOD FOR TESTING MOISTURE PERMEATION OF SHEET BODY, METHOD FOR MEASURING MOISTURE PERMEABILITY AND MOISTURE PERMEATION TESTING DEVICE FOR SHEET BODY

(71) Applicant: NITTO DENKO CORPORATION, Ibaraki-shi, Osaka (JP)

(72) Inventors: Kenji FURUTA, Ibaraki-shi, Osaka (JP); Tatsuya SUZUKI, Ibaraki-shi, Osaka (JP); Minami WATANABE, Ibaraki-shi, Osaka (JP)

(21) Appl. No.: 16/956,257

(22) PCT Filed: Dec. 27, 2018
(86) PCT No.: PCT/JP2018/048367

§ 371 Date: Jun. 19, 2020

(30) Foreign Application Priority Data
Dec. 28, 2017 (JP) 2017-253955
Jun. 15, 2018 (JP) 2018-114937
Dec. 27, 2018 (JP) 2018-244377

(51) Int. Cl. C09J 7/38; H05K 5/06; G01N 19/10; G11B 33/14

(52) U.S. Cl. CPC C09J 7/385; H05K 5/061; G01N 19/10; G11B 2005/0021; G11B 33/1486; C09J 7/383; G11B 33/1406

(57) ABSTRACT

Provided is a PSA sheet having excellent moisture resistance with reduced gas emission.

The sheet body provided by this invention is a laminate sheet body having a PSA layer on at least one face. The sheet body has a moisture permeability of less than 90 μg/cm² per 24 hour measurement period in in-plane direction of bonding interface of PSA layer, with the sheet body having an internal volume (bulk) forming a permeation channel that has a prescribed length of 2.5 mm, the moisture permeability determined based on a modified MOCON method, at a permeation cell temperature of 40° C., with humidistat gas at a temperature of 40° C. and 90% relative humidity supplied to a wet chamber. It also has an amount of thermally released gas of 10 μg/cm² or less, determined at 130° C., over 30 minutes, by gas chromatography/mass spectrometry.

### TECHNICAL FIELD

The present invention relates to a sheet body, an electronic part case, a method for testing moisture permeation of sheet body, a method for determining moisture permeability and a moisture permeation testing device for sheet body.

The present invention claims priority to Japanese Patent Applications No. 2017-253955 filed on Dec. 28, 2017, No. 2018-114937 filed on Jun. 15, 2018 and No. 2018-244377 filed on Dec. 27, 2018; and the entire content thereof is incorporated herein by reference.

### BACKGROUND ART

In general, pressure-sensitive adhesive (PSA) exists as a soft solid (a viscoelastic material) in a room temperature range and has a property to adhere easily to an adherend with some pressure applied. For such a property, PSA is widely used in a form of, for instance, an on-substrate PSA sheet having a PSA layer on a support substrate, for purposes such as bonding, fastening, protection and sealing in various applications. For instance, technical literatures related to PSA sheets that airtightly seal internal spaces of magnetic disc devices include Patent Documents 1 to 3. In this application, because the allowable maximum temperature is limited, PSA that does not require heat for press-bonding is preferably used as the bonding means.

### CITATION LIST

### Patent Literature

[Patent Document 1] Japanese Patent Application Publication No. 2014-162874

[Patent Document 2] Japanese Patent Application Publication No. 2017-014478

[Patent Document 3] Japanese Patent Application Publication No. 2017-160417

### SUMMARY OF INVENTION

### Technical Problem

These PSA sheets all comprise non-breathable substrates and are used in magnetic disc devices such as hard disc drives (HDD), in embodiments to seal their internal spaces where magnetic discs (typically HD) are contained. In particular, a void space that can be present between a cover member and a housing base member in which the magnetic disc is placed can be covered and sealed with a PSA sheet so as to obtain airtightness for the internal space of the device. Such airtight properties may be essential and particularly important in a type of device whose internal space is filled with a low-density gas such as helium in order to reduce the influence of air flow generated by the spinning disc. In an embodiment using the PSA sheet, the sealing structure can be made thinner than in a conventional magnetic disc device for which air-tightness has been assured with a gasket; and therefore, this embodiment is advantageous in increasing the density and capacity of a magnetic disc device. This embodiment does not require use of a liquid gasket. Thus, it can mitigate outgassing problems due to gasket.

Lately, studies are underway on magnetic disc devices using HAMR (heat-assisted magnetic recording) for further increases in capacity. In short, HAMR is a technology that uses a laser beam to increase their surface recording densities. In this technology, the presence of internal moisture attenuates the laser beam and badly impacts on the recording life (the number of times that it can be overwritten). Thus, it is desirable to exclude moisture as much as possible. About this aspect, in Patent Documents 2 and 3, cup methods are used to test moisture permeability of PSA sheets having aluminum layers. However, the cup method analysis of moisture permeability of PSA sheets fell short of quantifying water vapor permeation that is in a minute amount, yet still capable of affecting HAMR.

Accordingly, to further enhance the water vapor-blocking properties (or moisture resistance) of PSA sheets, the present inventors have conducted studies including test methods for moisture permeability to identify moisture permeable channels through the PSA sheets and established a novel, effective method for testing moisture permeability (a method for accurately assessing through-bonding-plane moisture permeability, i.e. moisture permeability in in-plane direction of bonding interface). As a result of researching countermeasures for moisture permeation based on the novel test method, a PSA sheet having a high level of moisture resistance capable of extending HAMR life and the like has been successfully developed, whereby the present invention has been completed. In other words, an objective of the present invention is to provide a sheet body having excellent moisture resistance. Another objective of this invention is to provide an electronic part casing using the sheet body. Other objectives of this invention are to provide a novel method for testing moisture permeation of sheet body, a method for determining moisture permeability and a moisture permeation testing device for sheet body.

### Solution to Problem

The present description provides a PSA sheet comprising a moisture-impermeable layer and a PSA layer provided on one face of the moisture-impermeable layer. The PSA sheet has a moisture permeability (amount of moisture permeated over 24 hours/area of PSA layer) below 90 μg/cm² in in-plane direction of bonding interface of PSA sheet, measured at a permeation distance of 2.5 mm over a 24-hour period based on the MOCON method (equal-pressure method). It also has an amount of thermally released gas of 10 μg/cm² or less, determined at 130° C. for 30 minutes by gas chromatography/mass spectrometry (GC-MS).

Because the moisture permeability is limited to up to the prescribed value in directions lying along the bonding surface, the PSA sheet in this embodiment can prevent moisture permeation in the PSA sheet's thickness direction with the moisture-impermeable layer as well as moisture permeation in in-plane direction of bonding interface (in directions perpendicular to the thickness direction of the PSA sheet). The amount of gas thermally released by the PSA sheet is highly limited as well. Such a PSA sheet can be preferably used in an application for which the presence of moisture and volatile gas is undesirable. For instance, when the PSA sheet disclosed herein is used as a sealing material in a magnetic disc device, it is possible to greatly limit changes (typically increases) in internal humidity that may affect the normal and highly precise operation of the device as well as introduction of gas (siloxane gas, etc.) into the system.

The PSA sheet according to a preferable embodiment has a 180° peel strength (adhesive strength) of 3 N/20 mm or greater to a stainless steel plate. For instance, when the PSA sheet is used to seal the internal space of a sort of magnetic disc device, the PSA sheet having such adhesive strength can adhere well to the adherend, providing good sealing properties.

In a preferable embodiment of the PSA sheet disclosed herein, the PSA layer has a storage modulus G′(25° C.) less than 0.5 MPa at 25° C. With the use of the PSA layer having a storage modulus G′(25° C.) of at least the prescribed value, the PSA layer is highly wet and tightly adheres to the adherend's surface, whereby excellent moisture resistance is likely to be obtained.

The PSA sheet according to a preferable embodiment shows a displacement less than 2 mm in a shear holding power test carried out with a 1 kg load at 60° C. for one hour. The PSA sheet satisfying this property can provide good holding power even when used at a relatively high temperature.

In a preferable embodiment of the PSA sheet disclosed herein, the PSA layer is a rubber-based PSA layer comprising a rubber-based polymer as a base polymer, an acrylic PSA layer comprising an acrylic polymer as a base polymer, or a rubber-acrylic blend PSA layer comprising a rubber-based polymer and an acrylic polymer as base polymers. The use of rubber-based and acrylic PSA layers preferably brings about both excellent moisture resistance and reduced gas emission.

In a preferable embodiment of the PSA sheet disclosed herein, the PSA layer is the rubber-based PSA layer. In the rubber-based polymer, at least one species of monomer selected from the group consisting of butene, isobutylene and isoprene is polymerized. The use of the monomer in the rubber-based polymer can preferably achieve excellent moisture resistance.

In a preferable embodiment of the PSA sheet disclosed herein, the rubber-based PSA layer comprises a rubber-based polymer A and a rubber-based polymer B. In the rubber-based polymer A, isobutylene is polymerized, accounting for at least 50% by weight of the polymer. In the rubber-based polymer B, isobutylene and isoprene are copolymerized. The PSA sheet having the rubber-based PSA layer can provide superior moisture resistance.

The PSA sheet disclosed herein has excellent moisture resistance with reduced gas emission. Thus, it is preferably used for sealing the internal space of a magnetic disc device where entry of moisture and gas needs to be limited. The art disclosed herein provides a magnetic disc device comprising a PSA sheet disclosed herein. The PSA sheet may serve to seal the internal space of the magnetic disc device. In the magnetic disc device in such an embodiment, the PSA sheet is relatively thin, yet provides moisture resistance and air-tight properties; and therefore, as compared to a conventional gasket-type product, the capacity can be further increased with a lower amount of released gas. In particular, with the use of the PSA sheet disclosed herein in a HAMR magnetic disc device, a magnetic recording device having a higher density can be obtained.

The present description provides a method for measuring the moisture permeability of a PSA sheet. The measurement method includes (A) a step of obtaining a metal plate having an opening; (B) a step of preparing a measurement sample by adhering a PSA sheet to the metal plate to cover the opening; (C) a step of placing the measurement sample between a dry chamber and a wet chamber in a moisture permeability measurement device; and (D) a step of quantifying moisture permeation using the moisture permeability measurement device to determine the moisture permeability of the PSA sheet from the measured value. This method enables highly precise quantification of moisture permeation in an in-plane direction of the PSA sheet, whose degree of influence has been previously unknown. More specifically, differences in moisture permeability in in-plane direction of bonding interface can be detected as significant differences among different samples that have shown similar values in quantification of moisture permeation by conventional cup methods. By employing this method, moisture resistance can be tested at a higher level. This leads to studies on and creation of products having greater moisture resistance as well as creation of environments more strictly free of water vapor.

In a preferable embodiment, at the bonding interface between the PSA sheet and the metal plate, the ratio (W/L) of the bonding width W (moisture permeation distance) to the bonding length L (peripheral length of the opening in the metal plate) is 1/10 or less. The bonding length L is preferably 100 mm or greater. The bonding width W is preferably 1 mm to 10 mm. The peripheral shape of the opening in the metal plate is preferably a circle, triangle or quadrangle (particularly preferably a square, rectangle or rhomboid). The quantification of moisture permeation is preferably carried out based on the MOCON method (equal-pressure method).

The present description also provides a moisture permeability measurement device. The moisture permeability measurement device has a first chamber, a second chamber, and a partition plate placed between the first chamber and the second chamber. The partition plate has an opening communicating between the first and second chambers. According to such an embodiment, by suitably setting the first and second chambers to differ in humidity and adhering the measurement object (typically a PSA sheet) to cover the partition plate's opening, it is possible to evaluate the level of moisture permeation in in-plane direction of adhesion interface of the measurement object. For instance, this testing device enables highly precise quantification of moisture permeability in in-plane direction of bonding interface of PSA sheet, whose degree of influence has been previously unknown. This leads to studies on and creation of products having greater moisture resistance as well as creation of environments more strictly free of water vapor.

The present description also provides a test instrument used for determining moisture permeability in in-plane direction of bonding interface of a PSA sheet. The test instrument has a plate member having an opening. The use of such a test instrument enables highly precise measurement of moisture permeability in in-plane direction of bonding interface of a PSA sheet. More specifically, by adhering a PSA sheet to be tested so as to cover the opening when placed in the moisture permeability measurement device, the moisture permeation in in-plane direction of bonding interface of the PSA sheet can be quantified with high precision.

The present description provides a laminate sheet body having a PSA layer on at least one face, wherein the sheet body has a moisture permeability of less than 90 μg/cm² per 24 hour measurement period in in-plane direction of bonding interface of PSA layer, with the sheet body having an internal volume (bulk) forming a permeation channel that has a prescribed length of 2.5 mm, the moisture permeability determined based on a modified MOCON method, at a permeation cell temperature of 40° C., with humidistat gas at a temperature of 40° C. and 90% relative humidity supplied to a wet chamber; and the sheet body has an amount of thermally released gas of 10 μg/cm² or less, measured at 130° C., over 30 minutes, by gas chromatography/mass spectrometry.

It is noted that the sheet body in the art disclosed herein can be a combination of technical matters related to the PSA sheet disclosed herein (the aforementioned PSA sheet and the PSA sheet described later in detail; the same applies, hereinafter). Thus, the sheet body disclosed herein can have features (including all technical features such as configuration, structure, shape, composition, properties, etc.; the same applies, hereinafter) that the PSA sheet disclosed herein may have. The PSA sheet in the art disclosed herein may be a combination of technical matters related to the sheet body disclosed herein. Thus, the PSA sheet disclosed herein can have possible features of the sheet body disclosed herein.

As used herein, the “sheet body's internal volume” includes the interior and the interface (bonding interface) of the sheet. As used herein, the “in-plane directions of bonding interface” of a PSA layer, PSA sheet or sheet body (laminate sheet) are directions along the bonding interface, typically referring to directions vertically intersecting the thickness direction of the PSA layer, PSA sheet or sheet body (laminate sheet). The “moisture permeability in in-plane direction of bonding interface” refers to the moisture permeability determined from the moisture content of moist gas (possibly humidistat gas) passing in one direction having the prescribed permeation distance (2.5 mm) among the in-plane directions. In particular, the moisture permeability is determined by the method described later.

The sheet body preferably has a 180° peel strength of 3 N/20 mm or greater to a stainless steel plate, determined based on JIS Z 0237:2009.

The PSA layer preferably has a storage modulus below 0.5 MPa at 25° C. when the PSA layer has a thickness of 2 mm, placed between two flat plates and subjected to viscoelasticity measurement.

The sheet body shows a displacement less than 2 mm in a shear holding power test carried out with a 1 kg load at 60° C. for one hour.

The PSA layer preferably has a thickness of 3 μm or greater and 100 μm or less.

The sheet body preferably has a tensile modulus greater than 1000 N/cm and less than 3500 N/cm in a tensile test at an inter-chuck distance of 20 mm, at a speed of 50 mm/min.

The PSA layer preferably has a peak loss factor of 0.8 or greater.

The PSA layer is preferably a rubber-based PSA layer comprising a rubber-based polymer, an acrylic PSA layer comprising an acrylic polymer, or a rubber-acrylate blend PSA layer obtainable by blending a rubber-based polymer and an acrylic polymer.

It is preferable that the PSA layer is the rubber-based PSA layer; and in the rubber-based polymer, at least one species of monomer selected from the group consisting of butene, isobutylene and isoprene is polymerized.

The rubber-based PSA layer comprises a rubber-based polymer A and a rubber-based polymer B. In the rubber-based polymer A, isobutylene is polymerized, accounting for at least 50% (by weight) thereof. In the rubber-based polymer B, isobutylene and isoprene are copolymerized.

The present description provides a method for testing moisture permeation proceeding from a periphery (or an edge face) of a sheet body having peripheries through the sheet body's internal volume via its surface to the outside, the method characterized by using a permeation cell comprising a test piece-loading plate that has an opening in a location away from its peripheries (or edge faces), with the plate partitioning the cell interior into a wet chamber and a dry chamber; placing the sheet body as a test piece on the test piece-loading plate, with the sheet body located where the distance along the sheet body between the sheet body's periphery and the opening of the test piece-loading plate forms a permeation channel of a prescribed length through the internal volume (bulk) of the sheet body, and the sheet body facing the wet chamber; supplying humidistat gas at prescribed temperature and relative humidity and dry gas to the wet chamber and to the dry chamber, respectively, under designated conditions; and detecting the relative humidity of emission gas released from the dry chamber.

The present description provides a method for testing moisture permeation from a periphery (or an edge face) of a sheet body having peripheries through the sheet body's internal volume via its surface to the outside, the method characterized by using a permeation cell comprising a test piece-loading plate that has an opening in a location away from its peripheries (or edge faces), with the plate partitioning the interior into a wet chamber and a dry chamber; placing the sheet body as a test piece on the test piece-loading plate, with the sheet body located where the distance along the sheet body between the sheet body's periphery and the opening of the test piece-loading plate forms a permeation channel of a prescribed length through the internal volume (bulk) of the sheet body, and the sheet body facing the wet chamber; placing a moisture-impermeable layer on top of the sheet body; supplying humidistat gas at prescribed temperature and relative humidity and dry gas to the wet chamber and to the dry chamber, respectively, under designated conditions; and detecting the relative humidity of emission gas released from the dry chamber.

The “outside” means a space opposing the space where peripheries of the two spaces divided by the sheet body are present; for instance, it means the interior of the casing in an electronic part case; in permeability measurement, it corresponds to the dry chamber side (detection chamber side).

The moisture permeation test method in the art disclosed herein can be a combination of technical matters related to the moisture permeability measurement method disclosed herein (the aforementioned moisture permeability measurement method and the moisture permeability measurement method described later in detail; the same applies, hereinafter). Thus, the moisture permeation test method disclosed herein can have features that the moisture permeability measurement method disclosed herein may have. The moisture permeability measurement method in the art disclosed herein may be a combination of technical matters related to the moisture permeation test method disclosed herein. Thus, the moisture permeability measurement method disclosed herein can have possible features of the moisture permeation test method disclosed herein.

The present description provides a method for the measuring moisture permeability of a sheet body that comprises a moisture-impermeable layer and a PSA layer laminated on a surface of the moisture-impermeable layer and that has a periphery, with permeation proceeding from the periphery of the sheet body in an in-plane direction through the sheet body's internal volume, based on a modified MOCON method, the method characterized by comprising the following steps: adhering the PSA layer with the sheet body covering an opening in a test piece-loading plate and forming a permeation channel of 2.5 mm through the sheet body's internal volume (bulk); and measuring the permeability of the sheet body based on a modified MOCON method.

The present description provides an apparatus for testing moisture permeation that proceeds from a periphery (or an edge face) of a sheet body having peripheries through the sheet body's internal volume via its surface to the outside, the apparatus characterized by having a permeation cell that comprises a test piece-loading plate having an opening in a location away from its peripheries (or edge faces) with the plate partitioning the interior into a wet chamber and a dry chamber, a humidistat (moisture-adjusted) gas supply system that supplies humidistat gas at prescribed temperature and relative humidity to the dry chamber, a dry gas supply system that supplies dry gas to the dry chamber, and a humidity sensor connected to the dry chamber to detect the gas temperature inside the dry chamber; the apparatus having a constitution in which the sheet body as a test piece is placed on the test piece-loading plate, with the sheet body located where the distance along the sheet body between the sheet body's periphery and the opening of the test piece-loading plate forms a permeation channel of a prescribed length through the internal volume (bulk) of the sheet body, and the sheet body facing the wet chamber; and the relative humidity of emission gas released from the dry chamber is detected.

The present description provides an apparatus for testing moisture permeation that proceeds from a periphery (or an edge face) of a sheet body having peripheries through the sheet body's internal volume via its surface to the outside, the apparatus characterized by having a permeation cell that comprises a test piece-loading plate having an opening in a location away from its peripheries (or edge faces) with the plate partitioning the interior into a wet chamber and a dry chamber, a humidistat (moisture-adjusted) gas supply system that supplies humidistat gas at prescribed temperature and relative humidity to the dry chamber, a dry gas supply system that supplies dry gas to the dry chamber, and a humidity sensor connected to the dry chamber to detect the gas temperature inside the dry chamber; and the apparatus having a constitution in which the sheet body as a test piece is placed on the test piece-loading plate, with the sheet body located where the distance along the sheet body between the sheet body's periphery and the opening of the test piece-loading plate forms a permeation channel of a prescribed length through the internal volume (bulk) of the sheet body, the sheet body facing the wet chamber; a moisture-impermeable layer is placed on top of the sheet body; and the relative humidity of emission gas released from the dry chamber is detected.

The moisture permeation testing device in the art disclosed herein can be a combination of technical matters related to the moisture permeability measurement device disclosed herein (the aforementioned moisture permeability measurement device and the moisture permeability measurement device described later in detail; the same applies, hereinafter). Thus, the moisture permeation testing device disclosed herein can have features that the moisture permeability measurement device disclosed herein may have. The moisture permeability measurement device in the art disclosed herein may be a combination of technical matters related to the moisture permeation testing device disclosed herein. Thus, the moisture permeability measurement device disclosed herein can have possible features of the moisture permeation testing device disclosed herein.

The present description provides an apparatus for measuring the moisture permeability in an in-plane direction of a measurement object based on a modified MOCON method, with the apparatus having a hollow cell and a partition plate dividing the hollow cells interior into a wet chamber and a dry chamber for the measurement based on the modified MOCON method, with the partition plate (1) being placed with its first face opposing the wet chamber and its second face opposing the dry chamber, (2) having an opening communicating between the wet chamber and the dry chamber, and (3) having a constitution that blocks moisture from passing between the wet chamber and the dry chamber; and the apparatus has a constitution in which a measurement object is placed on the partition plate to cover the opening, with the measurement object being impermeable in its thickness direction, and moisture permeability is measured based on the modified MOCON method.

The measurement object is a multi-layer structure comprising a PSA layer and a moisture-impermeable layer. The PSA layer is preferably bonded to the partition plate.

The present description also provides an electronic part casing that has an encasing member having an opening, and a closing member attached to the encasing member, with the encasing member internally having a low-pressure or inert gas space in which an electronic part is housed, the electronic part casing characterized by the following: a sealing member that is provided to a location between the closing member and the encasing member where the opening of the encasing member is sealed or provided onto the outside of the closing member, wherein the sealing member is a sheet body having a periphery and is placed between the encasing member and the closing member or placed on the outside of the closing member, with the periphery exposed at least partially to an external space; the sealing member is essentially moisture-impermeable in the thickness direction of the sheet body; and the sheet body has a moisture permeability through bulk in in-plane direction of bonding interface of PSA layer of less than 5×10⁻¹ g/m² per 24-hour measurement period, with the sheet body having an internal volume (bulk) forming a permeation channel that has a prescribed length of 2.5 mm, and the moisture permeability determined based on a modified MOCON method, at a permeation cell temperature of 40° C., with humidistat gas at a temperature of 40° C. and 90% relative humidity supplied to a wet chamber.

The sealing member is preferably bonded, with a 180° peel strength of 3 N/20 mm or greater, to the encasing member and/or to the closing member.

The electronic part preferably includes a magnetic disc.

It is noted that the electronic part casing in the art disclosed herein can be a combination of technical matters related to the magnetic disc device disclosed herein (the aforementioned magnetic disc device and the magnetic disc device described later in detail; the same applies, hereinafter). Thus, the electronic part casing disclosed herein can have features that the magnetic disc device disclosed herein may have. The magnetic disc device in the art disclosed herein may be a combination of technical matters related to the electronic part casing disclosed herein. Thus, the magnetic disc device disclosed herein can have possible features of the electronic part casing disclosed herein.

### BRIEF DESCRIPTION OF DRAWINGS

FIG. 1 shows a cross-sectional diagram schematically illustrating a constitutional example of the PSA sheet.

FIG. 2 shows a schematic diagram of the moisture permeability measurement method and moisture permeability measurement device.

FIG. 3 shows an enlarged top view of a sample used in determining the moisture permeability.

FIG. 4 shows a cross-sectional diagram schematically illustrating the magnetic disc device according to an embodiment.

FIG. 5 shows a cross-sectional diagram schematically illustrating the magnetic disc device according to another embodiment.

### DESCRIPTION OF EMBODIMENTS

Preferable embodiments of the present invention are described below. Matters necessary to practice this invention other than those specifically referred to in this description can be understood by a person skilled in the art based on the disclosure about implementing the invention in this description and common technical knowledge at the time the application was filed. The present invention can be practiced based on the contents disclosed in this description and common technical knowledge in the subject field. In the drawings referenced below, a common reference numeral may be assigned to members or sites producing the same effects, and redundant descriptions are sometimes omitted or simplified. The embodiments described in the drawings are schematized for clear illustration of the present invention, and do not necessarily represent the accurate size or reduction scale of an actual product of the PSA sheet or magnetic disc device of this invention or of the moisture permeability measurement device.

As used herein, the term “PSA” refers to, as described earlier, a material that exists as a soft solid (a viscoelastic material) in a room temperature range and has a property to adhere easily to an adherend with some pressure applied. As defined in “Adhesion: Fundamentals and Practice” by C. A Dahlquist (McLaren & Sons (1966), P. 143), in general, PSA referred to herein can be a material that has a property satisfying complex tensile modulus E* (1 Hz)<10⁷ dyne/cm² (typically, a material that exhibits the described characteristics at 25° C.).

The concept of PSA sheet herein may encompass so-called PSA tape, PSA labels, PSA film, etc. The PSA sheet disclosed herein can be in a roll or in a flat sheet. Alternatively, the PSA sheet may be processed into various shapes.

### <Constitution of PSA Sheet>

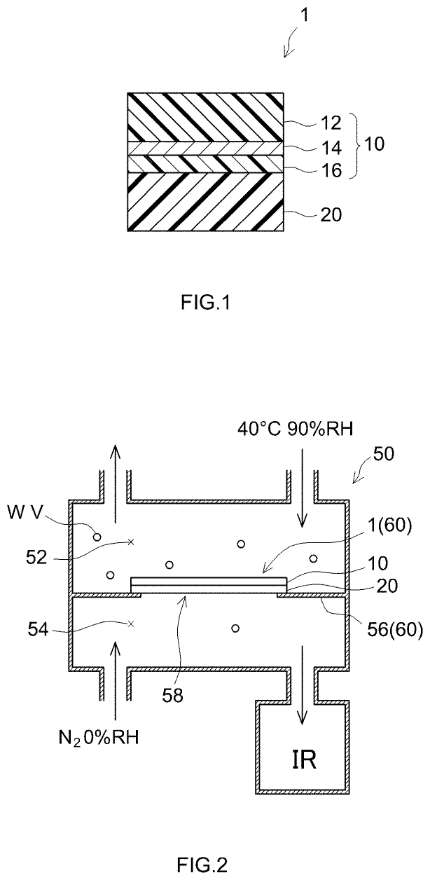

The PSA sheet disclosed herein can be, for instance, an adhesively single-faced PSA sheet having a cross-sectional structure as shown in FIG. 1. A PSA sheet 1 comprises a moisture-impermeable layer 10 and a PSA layer 20 supported on a first face of moisture-impermeable layer 10. In particular, moisture-impermeable layer 10 is a layered body (laminate film) in which a first resin layer 12, an inorganic layer 14 and a second resin layer 16 are layered in this order. The first resin layer 12 placed on the first face side of inorganic layer 14 forms an outer surface of PSA sheet 1 while the second resin layer 16 is placed on the second face side of inorganic layer 14, that is, the PSA layer 20 side. From the standpoint of the moisture resistance, PSA layer 20 is formed continuously over the entire first face of moisture-impermeable layer 10 at least in the area that bonds to an adherend. PSA sheet 1 prior to use (before applied to the adherend) may be protected with a release liner (not shown in the drawing) having a release face at least on the PSA layer 20 side surface.

### <Properties of PSA Sheet>

The PSA sheet disclosed herein is characterized by having a moisture permeability below 90 μg/cm² in in-plane direction of bonding interface of PSA sheet, determined per 24-hour period at a permeation distance of 2.5 mm based on the MOCON method (equal-pressure method). This limits moisture permeation in in-plane directions of bonding interface (vertical to the thickness direction of the PSA sheet) and excellent moisture resistance can be obtained. The moisture permeability in in-plane direction of bonding interface is preferably below 60 μg/cm², more preferably below 30 μm/cm², or yet more preferably below 15 μg/cm² (e.g. below 9 μg/cm²).

In particular, the moisture permeability in in-plane direction of bonding interface is determined by the method described below.

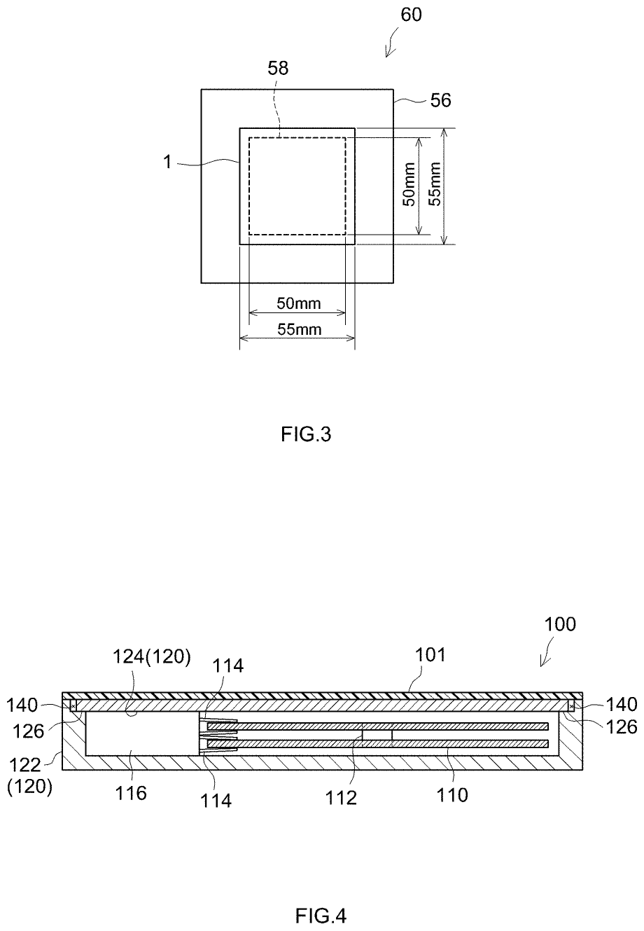

(1) A metal plate having a 50 mm square opening at the center is obtained. FIG. 2 outlines a moisture permeability measurement device 50 used for determining the moisture permeability. In FIG. 2, reference number 56 shows the metal plate and reference number 58 shows the opening made in metal plate 56. FIG. 3 shows a top view of metal plate 56 having opening 58.
(2) The PSA sheet subject to measurement is cut to a 55 mm square and applied to cover the opening in the metal plate to prepare a measurement sample. The PSA sheet is applied to the metal plate to have a bonding width of 2.5 mm at each side of the opening. The PSA sheet is applied at a temperature of 23±2° C. and RH 50±10% by rolling a 2 kg roller back and forth once. The bonding width of the PSA sheet at each side of the opening is the width of the band of bonding interface between the PSA sheet and the metal plate, which is the permeation distance (mm) in an in-plane direction of bonding interface of the PSA sheet. The peripheral length of the opening in the metal plate is referred to as the bonding length (mm). The bonding length (mm) is the total length of the band of bonding interface exposed to water vapor. In particular, the measurement sample has a structure shown by reference number 60, formed of metal plate 56 and PSA sheet 1 applied to metal plate 56 as shown in FIG. 3.
(3) Based on Method B of JIS K 7129:2008, the measurement sample is placed between a dry chamber and a wet chamber in the moisture permeability measurement device. In particular, as shown in FIG. 2, a measurement sample 60 is positioned between a dry chamber 54 and a wet chamber 52. In FIG. 2, WV represents water vapor.
(4) Based on the MOCON method (equal-pressure method), conditioning is carried out for 3 hours. Subsequently, as shown in FIG. 2, at 40° C. and 90% RH (relative humidity), the amount (μg) of moisture that has permeated in an in-plane direction of bonding interface of PSA sheet per one hour is determined.
(5) To obtain the moisture permeability (μg/cm²) in in-plane direction of bonding interface, the amount of moisture permeation per 24 hours converted from the measurement value and the PSA layer's surface area (permeation distance×bonding length) are substituted into the equation:

Moisture permeability (μg/cm²)=amount of moisture permeation (μg)/(permeation distance (cm)×bonding length (cm))

As used herein, the “moisture permeability below 90 μg/cm² in in-plane direction of bonding interface of PSA sheet, determined at a permeation distance of 2.5 mm over a 24-hour period based on the MOCON method (equal-pressure method)” (or the “moisture permeability (μg/cm²) per 24-hour measurement period in in-plane direction of bonding interface of PSA sheet determined based on a modified MOCON method, at a permeation distance of 2.5 mm”) can be a value obtained by a measurement over a 24-hour period, but it is not limited to this; as described above, it can be a 24-hour value converted from a measurement taken for a certain time period (e.g. one hour). The measurement time can be longer than one hour (preferably about 6 hours; the same applies to working examples described later) and the value per 24 hours converted from this measurement value can be used as well.

The kind of metal plate is not particularly limited. For instance, an aluminum plate can be used. The size of the metal plate is not particularly limited, either. In accordance with the size of testing device, etc., for instance, a 100 mm square plate can be used. It is suitable to use a metal plate having a smooth surface, for instance, one having a mean arithmetic roughness Ra of about 3 μm or less. In particular, an aluminum plate (0.3 mm thick, surface roughness: mirror finished, Ra 0.1 μm) is used. As the testing device, product name PERMATRAN-W3/34G available from MOCON, Inc. or a comparable product can be used. In a testing device of this type, N₂ gas at 90% RH can be supplied to the wet chamber and N₂ gas at 0% RH can be supplied to the dry chamber. This maintains the two chambers divided by the measurement sample at an equal pressure. For the measurement, the gas flow is set at 10 mL/min. In the testing device, the water vapor concentration is measured by an infrared sensor (indicated as “IR” in FIG. 8), but the means of detection is not limited to this. The position of the measurement sample in the testing device is not particularly limited. The adhesive face of the PSA sheet can be placed either on the wet chamber side or on the dry chamber side. The same measurement method is employed in the working examples described later. The measurement value of moisture permeation is used as the amount (μg) of moisture permeated upon zero-point correction based on the measurement value of an aluminum plate with no opening. The same measurement method is employed in the working examples described later.

In this description, the method is also referred to as the “modified MOCON method” and it may mean the moisture permeation test method for sheet body defined as follows: It can be a method for testing moisture permeation from a periphery of a sheet body through the sheet body's internal volume, the method using a permeation cell comparable to a permeation cell 2 illustrated in Fig. B.1 in Annex B of JIS K 7129:2008, wherein, in place of a test piece 1, a test piece-loading plate is placed, with the plate having an opening in a location away from the rim; wherein the sheet body as a test piece is placed on the test piece-loading plate, with the sheet body located where the distance along the sheet body between the sheet body's periphery and the opening of the test piece-loading plate forms a permeation channel of a prescribed length through the internal volume (bulk) of the sheet body, and the sheet body facing a wet chamber 12, while moisture permeation is at an essentially negligible level along the interface between the sheet body and the test piece-loading plate; humidistat gas at prescribed temperature and relative humidity and dry gas are supplied to wet chamber 12 and to dry chamber 11, respectively, under the conditions described in Table B.1 in Annex B of JIS K 7129:2008 or under other designated conditions; and the relative humidity of emission gas released from dry chamber 11 is detected by a sensor 6. The permeation cell in this test method may also be referred to as a test cell and is included in moisture permeability measurement device 50. In particular, the permeation cell is formed with dry chamber 54 and wet chamber 52 in moisture permeability measurement device 50. In the test method, the temperature of the permeation cell is set at 40° C.

The PSA sheet disclosed herein suitably is characterized by having an amount of thermally released gas of 10 μg/cm² or less (in particular, 0 to 10 μg/cm²) when determined at 130° C. for 30 minutes by GC-MS. The PSA sheet with such highly-limited thermal gas release can be preferably used in an application (typically a magnetic disc device) for which the presence of volatile gas is undesirable. When the PSA sheet satisfying this property is used as a sealing material for a magnetic disc device, it can highly inhibit internal contamination with siloxane and other gas that affect the device. The amount of thermally released gas is preferably 7 μg/cm² or less, more preferably 5 μg/cm² or less, yet more preferably 3 μg/cm² or less, or particularly preferably 1 μg/cm² or less.

The amount of thermally released gas is determined based on the dynamic headspace method. In particular, a PSA sheet subject to measurement is cut out to a 7 cm² size to obtain a measurement sample. The measurement sample is sealed in a 50 mL vial and heated at 130° C. for 30 minutes, using a headspace autosampler. As the headspace autosampler, a commercial product can be used without particular limitations. For instance, product name EQ-12031HSA available from JEOL Ltd., or a comparable product can be used. The total amount of gas released from the measurement sample is determined by gas chromatography/mass spectrometry (GC-MS). A commercial GC-MS can be used. The amount of thermally released gas is the amount of gas released per unit surface area of PSA sheet (in μg/cm²). The same measurement method is employed in the working examples described later.

The PSA sheet disclosed herein has a 180° peel strength to stainless steel (an adhesive strength) of preferably 3 N/20 mm or greater, when determined based on JIS Z 0237:2009. Having such an adhesive strength, the PSA sheet can bond well to an adherend to provide good sealing. The adhesive strength is more preferably 5 N/20 mm or greater, yet more preferably 8 N/20 mm or greater, or particularly preferably 10 N/20 mm or greater (e.g. 12 N/20 mm or greater). The maximum adhesive strength is not particularly limited. From the standpoint of preventing left-over adhesive residue, it is suitably about 20 N/20 mm or less (e.g. about 15 N/20 mm or less).

The adhesive strength of a PSA sheet is determined by the following method: A PSA sheet subject to measurement is cut to a 20 mm wide, 100 mm long size to prepare a test piece. In an environment at 23° C. and 50% RH, the adhesive face of the test piece is press-bonded to a stainless steel plate (SUS304BA plate) to obtain a measurement sample. The press-bonding is carried out by rolling a 2 kg roller back and forth once. The measurement sample is left standing in an environment at 23° C. and 50% RH for 30 minutes. Subsequently, using a tensile tester, based on JIS Z 0237:2009, the peel strength (N/20 mm) is determined at a tensile speed of 300 mm/min at a peel angle of 180°. As the tensile tester, Precision Universal Tensile Tester Autograph AG-IS 50N available from Shimadzu Corporation or a comparable product can be used. The same measurement method is employed in the working examples described later.

The PSA sheet disclosed herein preferably has a 180° peel strength to hard disc drive casing material (HDD adhesive strength) of 1 N/20 mm or greater. The PSA sheet having such an HDD adhesive strength can adhere well to an HDD casing to provide good sealing properties. The adhesive strength is preferably 2 N/20 mm or greater, more preferably 3 N/20 mm or greater, or particularly preferably 4 N/20 mm or greater (e.g. 5 N/20 mm or greater). The maximum HDD adhesive strength is not particularly limited. From the standpoint of preventing leftover adhesive residues, it is suitably about 15 N/20 mm or less (e.g. about 10 N/20 mm or less).

The HDD adhesive strength of a PSA sheet is determined by the following method. A casing (housing case) having the PSA sheet adhered thereon is left standing for 30 minutes in an environment at 23° C. and 50% RH. Subsequently, using a tensile tester, based on JIS Z 0237:2009, the peel strength of the PSA sheet is determined at a tensile speed of 300 mm/min at a peel angle of 180°. As the tensile tester, Precision Universal Tensile Tester Autograph AG-IS 50N available from Shimadzu Corporation or a comparable product can be used. The same measurement method is employed in the working examples described later. In general, the material forming the electronic part casing (e.g. an HDD case) used in this measurement can be stainless steel (SUS304, etc.) or an aluminum material with bisphenol A epoxy resin coated by cationic electrodeposition. The PSA sheet disclosed herein may bond to an adherend formed of such a material, with at least the prescribed adhesive strength.

The PSA sheet disclosed herein preferably shows a displacement less than 2 mm in a shear holding power test carried out with a 1 kg load at 60° C. for one hour. The PSA sheet satisfying this property shows good holding power even when used at a relatively high temperature. The displacement in the shear holding power test is more preferably less than 1 mm, or yet more preferably less than 0.7 mm (e.g. less than 0.5 mm, or even less than 0.1 mm). The PSA sheet according to a particularly preferable embodiment shows no displacement (i.e. a displacement of about 0 mm) in the shear holding power test.

The shear holding power of a PSA sheet is determined by the following method: In particular, the PSA sheet subject to measurement is cut 10 mm wide, 20 mm long to prepare a test piece. In an environment at 23° C. and 50% RH, the adhesive face of the test piece is press-bonded to a stainless steel plate to obtain a measurement sample. The press-bonding is carried out by rolling a 2 kg roller back and forth once. The measurement sample is vertically suspended and left in an environment at 60° C. and 50% RH for 30 minutes. Subsequently, a 1 kg weight is attached to the free lower end of the test piece to start the test. The test is carried out for one hour and the distance that the test piece displaced (the displacement) is measured at one hour. The same measurement method is employed in the working examples described later.

The PSA sheet disclosed herein preferably has a tensile modulus per unit width in a prescribed range. In particular, the tensile modulus is preferably greater than 1000 N/cm, more preferably greater than 1400 N/cm, yet more preferably greater than 180° N/cm, or particularly preferably greater than 2200 N/cm. The PSA sheet having such a tensile modulus has suitable rigidity and is less susceptible to creasing. It tends to provide excellent handling properties as well. The tensile modulus is preferably less than 3500 N/cm, more preferably less than 3000 N/cm, or yet more preferably less than 2800 N/cm (e.g. less than 2600 N/cm). The PSA sheet having such a tensile modulus has good adherend conformability and can well conform in a bent state to an area of the adherend including a corner.

The tensile modulus per unit width of PSA sheet is determined as follows: In particular, the PSA sheet is cut to a 10 mm wide, 50 mm long strip to prepare a test piece. The two ends of the length of the test piece are clamped with chucks in a tensile tester. In an atmosphere at 23° C., at an inter-chuck distance of 20 mm, at a speed of 50 mm/min, a tensile test is conducted using the tensile tester to obtain a stress-strain curve. Based on the initial slope of the resulting stress-strain curve, the Young's modulus (N/mm²=MPa) is determined by linear regression of the curve between two specified strain points ε1 and ε2. From the product of the resulting value and the thickness of the PSA sheet, the tensile modulus per unit width (N/cm) can be determined. As the tensile tester, a commonly known or conventionally used product can be used. For instance, AUTOGRAPH AG-IS available from Shimadzu Corporation or a comparable product can be used.

The total thickness of the PSA sheet disclosed herein is not particularly limited. It is suitably about 6 μm or greater. From the standpoint of the moisture resistance and crease resistance, etc., it is preferably 25 μm or greater, more preferably 40 μm or greater, or yet more preferably 60 μm or greater. The total thickness is suitably about 1.2 mm or less. From the standpoint of the adherend conformability and of reducing the thickness and weight, it is preferably 200 μm or less, more preferably 150 μm or less, or yet more preferably 120 μm or less (e.g. less than 100 μm). The total thickness of a PSA sheet here refers to the combined thickness of the moisture-impermeable layer and the PSA layer, not including the thickness of the release liner described later.

### <PSA Layer>

### (Base Polymer)

In the art disclosed herein, the type of PSA forming the PSA layer is not particularly limited. The PSA may comprise, as its base polymer, one, two or more species of various rubber-like polymers such as rubber-based polymers, acrylic polymers, polyester-based polymers, urethane-based polymers, polyether-based polymers, silicone-based polymers, polyamide-based polymer and fluorine-based polymers that are known in the PSA field. From the standpoint of the moisture resistance and reduction of outgassing, it is preferable to use a rubber-based PSA comprising a rubber-based polymer as the base polymer or a PSA comprising an acrylic polymer as the base polymer. Other examples include a PSA comprising a rubber-based polymer and an acrylic polymer as the base polymer. In particular, a highly moisture-resistant rubber-based PSA layer is more preferable. When the PSA sheet disclosed herein is used in a magnetic disc device, it is desirable that the PSA is essentially free of a silicone-based polymer which may form siloxane gas.

The PSA sheet having a rubber-based PSA layer and the PSA sheet having an acrylic PSA layer are primarily discussed below; however, the PSA layer of the PSA sheet disclosed herein is not limited to layers formed of rubber-based PSA and acrylic PSA

The “base polymer” of PSA refers to the primary component among rubber-like polymers (polymers that exhibit rubber elasticity in a near-room temperature range) (i.e. a component accounting for more than 50% by weight of the rubber-like polymers) in the PSA.

### (Rubber-Based Polymer)

The PSA layer disclosed herein is preferably a rubber-based PSA layer formed from a PSA composition whose base polymer is a rubber-based polymer. Examples of the base polymer include various rubber-based polymers such as natural rubber; styrene-butadiene rubber (SBR); polyisoprene; a butene-based polymer comprising butene (referring to 1-butene as well as cis- or trans-2-butene) and/or 2-methylpropane (isobutylene) as the primary monomer(s); A-B-A block copolymer rubber and a hydrogenation product thereof, for instance, styrene-butadiene-styrene block copolymer rubber (SBS), styrene-isoprene-styrene block copolymer rubber (SIS), styrene-isobutylene-styrene block copolymer rubber (SIBS), styrene-vinyl isoprene-styrene block copolymer rubber (SVIS), styrene-ethylene-butylene-styrene block copolymer rubber (SEBS) which is a hydrogenation product of SBS, styrene-ethylene-propylene-styrene block copolymer rubber (SEPS) which is a hydrogenation product of SIS, and styrene-isoprene-propylene-styrene block copolymer (SIPS). Among these rubber-based polymers, solely one species or a combination of two or more species can be used. Favorable examples of the butene-based polymer include isobutylene-based polymers. Isobutylene-based polymers are highly hydrophobic due to their molecular structures. Thus, a PSA layer (isobutylene-based PSA layer) comprising an isobutylene-based polymer as the base polymer may have relatively low moisture permeability on its own. This is advantageous from the standpoint of preventing water vapor from permeating through the lateral surface of the PSA layer at an edges face of the PSA sheet. Such a PSA layer tends to have a good elastic modulus as well as excellent removability. Specific examples of the isobutylene-based polymer include polyisobutylene and isobutylene-isoprene copolymer (butyl rubber).

The starting monomer mixture to form the rubber-based polymer disclosed herein include one, two or more species of monomers selected among butene, isobutylene, isoprene, butadiene, styrene, ethylene and propylene. The rubber-based polymer is obtainable by polymerizing one, two or more species among the monomers exemplified above. In the starting monomer mixture to form the rubber-based polymer disclosed herein, the one, two or more species of monomers typically account for 50% or more by weight (e.g. 50% to 100% by weight), preferably 75% or more by weight, more preferably 85% or more by weight, or yet more preferably 90% or more by weight (e.g. 95% by weight or more). The ratio of these monomers in the entire starting monomer mixture can be 99% by weight or higher. The rubber-based polymer according to a preferable embodiment is obtainable by polymerizing one, two or more species of monomers selected among isobutylene, isoprene and butene. From the standpoint of reduction of outgassing, the styrene content in the starting monomer mixture is preferably less than 10% by weight or more preferably less than 1% by weight. The art disclosed herein can be preferably implemented in an embodiment where the starting monomer mixture is essentially free of styrene.

In a preferable embodiment of the PSA sheet disclosed herein, the isobutylene-based polymer accounts for more than 50% by weight (e.g. 70% by weight or more, or even 85% by weight or more) of the polymers in the PSA. The PSA may be essentially free of other polymers besides the isobutylene-based polymer. In such a PSA, for instance, the ratio of non-isobutylene-based polymer in the starting monomer mixture can be 1% by weight or lower or even below the detection limit.

As used herein, the term “isobutylene-based polymer” is not limited to isobutylene homopolymer (homo-isobutylene), but also encompasses a copolymer whose primary monomer is isobutylene (a copolymer primarily formed of isobutylene). The copolymer includes a copolymer in which isobutylene accounts for the highest ratio among the monomers forming the isobutylene-based polymer. In a typical copolymer, isobutylene may account for more than 50% by weight of the monomers, or even 70% by weight or more. Examples of the copolymer include a copolymer of isobutylene and butene (normal butylene), a copolymer (butyl rubber) of isobutylene and isoprene, vulcanized products and modified products of these. Examples of the copolymers include butyl rubbers such as regular butyl rubber, chlorinated butyl rubber, iodinated butyl rubber, and partially crosslinked butyl rubber. Examples of the vulcanized and modified products include those modified with functional groups such as hydroxy group, carboxy group, amino group, and epoxy group. The isobutylene-based polymer that can be preferably used from the standpoint of the moisture resistance, reduction of outgassing, and adhesive strength, etc., includes polyisobutylene and isobutylene-isoprene copolymer (butyl rubber). The copolymer can be a copolymer (e.g. an isobutylene-isoprene copolymer) of which the other monomers (isoprene, etc.) excluding isobutylene has a copolymerization ratio lower than 30% by mol.

As used herein, the “polyisobutylene” refers to a polyisobutylene in which the copolymerization ratio of monomers excluding isobutylene is 10% or lower (preferably 5% or lower) by weight. In particular, homo-isobutylene is preferable.

The molecular weight of the isobutylene-based polymer is not particularly limited. For instance, a species having a weight average molecular weight (Mw) of about 5×10⁴ or higher (preferably about 15×10⁴ or higher, e.g. about 30×10⁴ or higher) can be suitably selected and used. The maximum Mw is not particularly limited and can be about 150×10⁴ or lower (preferably about 100×10⁴ or lower, e.g. about 80×10⁴ or lower). Several different isobutylene-based polymers varying in Mw can be used together. Having a Mw in these ranges, the PSA can be easily adjusted to have an elasticity in a preferable range and is likely to show good cohesive strength.

The molecular weight of the polyisobutylene is not particularly limited. For instance, a species having a Mw of about 1×10⁴ or higher can be suitably selected and used. The maximum Mw is not particularly limited and can be about 150×10⁴ or lower. From the standpoint of the moisture resistance, the Mw is preferably about 100×10⁴ or lower, for instance, about 80×10⁴ or lower. From the standpoint of the PSAs elastic modulus, cohesive strength and so on, the polyisobutylene according to a preferable embodiment has a Mw of preferably about 2×10⁴ or higher, more preferably about 3×10⁴ or higher, or yet more preferably about 5×10⁴ or higher (e.g. about 7×10⁴ or higher). From the standpoint of the moisture resistance, the Mw is preferably about 50×10⁴ or lower, more preferably about 30×10⁴ or lower, yet more preferably about 15×10⁴ or lower, or particularly preferably about 10×10⁴ or lower (e.g. below 10×10⁴). The polyisobutylene according to another embodiment may have a Mw of, for instance, about 5×10⁴ or higher, or preferably about 15×10⁴ or higher (typically about 30×10⁴ or higher).

While no particular limitations are imposed, as the polyisobutylene, it is preferable to use a species having a dispersity (Mw/Mn) (which is indicated as a ratio of weight average molecular weight (Mw) to number average molecular weight (Mn)) in a range of 3 to 7 (more preferably 3 to 6, e.g. 3.5 to 5.5). Several species of polyisobutylene varying in Mw/Mn can be used together.

The Mw and Mn values of an isobutylene-based polymer here refer to values based on polystyrene that are determined by gel permeation chromatography (GPC) analysis. As the GPC analyzer, for instance, model name HLC-8120 GPC available from Tosoh Corporation can be used.

The molecular weight of the butyl rubber is not particularly limited. For instance, a species having a Mw in a range between 5×10⁴ and 100×10⁴ can be suitably selected and used. In view of the balance between the ease of forming the PSA layer and tight adhesion (adhesive strength) to adherend, the butyl rubber has a Mw of preferably 10×10⁴ or higher, or more preferably 15×10⁴ or higher; and preferably 100×10⁴ or lower, or more preferably 80×10⁴ or lower. Several species of butyl rubber varying in Mw can be used together.

While no particular limitations are imposed, the butyl rubber has a dispersity (Mw/Mn) in a range between 3 and 8 or more preferably in a range between 4 and 7. Several species of butyl rubber varying in Mw/Mn can be used together. The butyl rubber's Mw and Mn can be determined by the same GPC analysis as the polyisobutylene.

The Mooney viscosity of the butyl rubber is not particularly limited. For instance, a butyl rubber having a Mooney viscosity ML₁₊₈(125° C.) between 10 and 100 can be used. In view of the balance between the PSA layer's ease of formation and tightness of bonding to adherend (adhesive strength), a butyl rubber having a Mooney viscosity ML₁₊₈(125° C.) of 15 to 80 (more preferably 30 to 70, e.g. 40 to 60) is preferable.

In a preferable embodiment of the art disclosed herein, the PSA layer comprises a rubber-based polymer A and a rubber-based polymer B as its base polymers. The rubber-based polymers A and Bare preferably both isobutylene-based polymers. The rubber-based polymer A according to a more preferable embodiment is an isobutylene-based polymer in which isobutylene is polymerized at a ratio of at least 50% (e.g. at least 70%, preferably at least 80%, or yet more preferably at least 90%) by weight; it is typically polyisobutylene. The rubber-based polymer B is an isobutylene-based polymer in which isobutylene and isoprene are copolymerized (i.e. an isobutylene-based copolymer); it is typically an isobutylene-isoprene copolymer. In the copolymer, the combined amount of isobutylene and isoprene as monomers accounts for typically at least 50% (e.g. at least 70%, preferably at least 80%, or yet more preferably at least 90%) by weight of the entire monomers. The use of rubber-based polymers A and B can bring the PSA layer's elastic modulus in a preferable range, and superior moisture resistance can be obtained.

In the embodiment using rubber-based polymers A and B together, because they vary in molecular weight, it is possible to preferably bring about moisture resistance based on the lower molecular polymer as well as adhesive properties (cohesive strength, etc.) based on the higher molecular weight polymer. From such a standpoint, in an embodiment in which the rubber-based polymer A has a relatively higher molecular weight, the ratio (M_{A}/M_{B}) of rubber-based polymer A's Mw (M_{A}) to rubber-based polymer B's Mw (M_{B}) is higher than 1, preferably about 2 or higher, more preferably about 3 or higher, or yet more preferably about 5 or higher (e.g. about 7 or higher). The maximum M_{A}/IM ratio value is suitably about 100 or lower, preferably about 50 or lower, more preferably about 20 or lower, or yet more preferably about 10 or lower (e.g. lower than 10). In an embodiment in which the rubber-based polymer B has a relatively higher molecular weight, the ratio (M_{B}/M_{A}) of rubber-based polymer B's Mw (M_{B}) to rubber-based polymer A's Mw (M_{A}) is higher than 1, preferably about 2 or higher, more preferably about 3 or higher, or yet more preferably about 5 or higher (e.g. about 7 or higher). The maximum M_{B}/M_{A} ratio value is suitably about 100 or lower, preferably about 50 or lower, more preferably about 20 or lower, or yet more preferably about 10 or lower (e.g. lower than 10).

In the embodiment using rubber-based polymers A and B together, from the standpoint of combining moisture resistance and adhesive properties based on their molecular weights, the rubber-based polymer A (e.g. polyisobutylene) has a Mw of suitably about 80×10⁴ or lower, preferably about 50×10⁴ or lower, more preferably about 30×10⁴ or lower, yet more preferably about 15×10⁴ or lower, or particularly preferably 10×10⁴ or lower (e.g. lower than 10×10⁴). The rubber-based polymer A has a Mw of suitably about 1×10⁴ or higher, preferably about 2×10⁴ or higher, more preferably about 3×10⁴ or higher, yet more preferably about 5×10⁴ or higher (e.g. about 7×10⁴ or higher). On the other hand, the rubber-based polymer B (e.g. isobutylene-isoprene copolymer) has a Mw of suitably about 5×10⁴ or higher, preferably 10×10⁴ or higher, more preferably 15×10⁴ or higher, or yet more preferably about 30×10⁴ or higher (e.g. 50×10⁴ or higher). The rubber-based polymer B has a Mw of suitably about 150×10⁴ or lower, preferably about 100×10⁴ or lower, more preferably about 80×10⁴ or lower, or yet more preferably about 70×10⁴ or lower (e.g. about 60×10⁴ or lower).

When rubber-based polymers A and B are used, their blend ratio can be suitably selected so as to obtain preferable elastic modulus, moisture resistance and adhesive properties disclosed herein. The weight ratio (PA/PB) of rubber-based polymer A (P) to rubber-based polymer B (P) can be, for instance, 95/5 to 5/95, preferably 90/10 to 10/90, more preferably 80/20 to 20/80, yet more preferably 70/30 to 30/70, or particularly preferably 60/40 to 40/60.

In a preferable embodiment, the dispersity (Mw/Mn) of the aforementioned base polymers at large is 3 or higher, or more preferably 4 or higher. According to the PSA comprising such base polymers, adhesive strength can be easily combined with resistance to leftover adhesive residue. It also brings the PSA layer's elastic modulus in a favorable range and good moisture resistance tends to be obtained. At or above a certain Mw/Mn value, the PSA can be obtained with a low solution viscosity for its Mw. The dispersity of the base polymers at large can also be 5 or higher, 6 or higher, or even 7 or higher. The maximum dispersity of the base polymers at large is not particularly limited; it is preferably 10 or lower (e.g. 8 or lower).

The art disclosed herein can be preferably implemented in an embodiment having a PSA layer formed of a PSA (a non-crosslinked PSA) in which the based polymers are not crosslinked. Here, the term “PSA layer formed of a non-crosslinked PSA” refers to a PSA layer that has not been subjected to an intentional treatment (i.e. crosslinking treatment, e.g. addition of a crosslinking agent, etc.) for forming chemical bonds among the base polymers.

### (Acrylic Polymer)

In an embodiment of the art disclosed herein, the PSA layer is an acrylic PSA layer comprising an acrylic polymer as the base polymer. The acrylic polymer is preferably a polymer of a starting monomer mixture that comprises an alkyl (meth)acrylate as the primary monomer and may further comprise a secondary monomer copolymerizable with the primary monomer. Here, the primary monomer refers to a component accounting for more than 50% by weight of the starting monomer mixture.

As used herein, the term “(meth)acryloyl” comprehensively refers to acryloyl and methacryloyl. Similarly, the term “(meth)acrylate” comprehensively refers to acrylate and methacrylate, and the term “(meth)acryl” comprehensively refers to acryl and methacryl.

As the alkyl (meth)acrylate, for instance, a compound represented by the following formula (1) can preferably be used:

CH₂═C(R¹)COOR² (1)

Here, R¹ in the formula (1) is a hydrogen atom or a methyl group. R² is an acyclic alkyl group having 1 to 20 carbon atoms (hereinafter, such a range of the number of carbon atoms may be indicated as “C₁₋₂₀”). From the standpoint of the PSAs storage modulus, adhesive properties, etc., an alkyl (meth)acrylate in which R² is a C₁₋₁₈ acyclic alkyl group is preferable; an alkyl (meth)acrylate in which R² is a C₂₋₁₄ acyclic alkyl group is more preferable; an alkyl (meth)acrylate in which R² is a C₄₋₁₂ acyclic alkyl group is even more preferable. In particular, it is preferable to use an alkyl acrylate as the primary monomer. The acyclic alkyl group includes linear and branched alkyl groups.

Examples of the alkyl (meth)acrylate in which R² is an acyclic C₁₋₂₀ alkyl group include methyl (meth)acrylate, ethyl (meth)acrylate, propyl (meth)acrylate, isopropyl (meth)acrylate, n-butyl (meth)acrylate, isobutyl (meth)acrylate, s-butyl (meth)acrylate, pentyl (meth)acrylate, isopentyl (meth)acrylate, hexyl (meth)acrylate, heptyl (meth)acrylate, 2-ethylhexyl (meth)acrylate, octyl (meth)acrylate, isooctyl (meth)acrylate, nonyl (meth)acrylate, isononyl (meth)acrylate, decyl (meth)acrylate, isodecyl (meth)acrylate, undecyl (meth)acrylate, dodecyl (meth)acrylate, tridecyl (meth)acrylate, tetradecyl (meth)acrylate, pentadecyl (meth)acrylate, hexadecyl (meth)acrylate, heptadecyl (meth)acrylate, octadecyl (meth)acrylate, nonadecyl (meth)acrylate, and eicosyl (meth)acrylate. These alkyl (meth)acrylates can be used singly as one species or in a combination of two or more species.

From the standpoint of the moisture resistance, as the primary monomer forming the acrylic polymer, it is preferable to use an alkyl (meth)acrylate having a higher number of carbon atoms in the acyclic alkyl group. With increasing number of carbon atoms of side-chain alkyl group in the acrylic polymer, the polymer tends to have higher hydrophobicity and greater moisture resistance. The number of carbon atoms in the acyclic alkyl group is 2 or higher, preferably 4 or higher, more preferably 8 or higher, yet more preferably 9 or higher, or particularly preferably 12 or higher.

The ratio of alkyl (meth)acrylate as the primary monomer in all the monomers forming the acrylic polymer is preferably 60% by weight or higher, more preferably 70% by weight or higher, or yet more preferably 75% by weight or higher (e.g. 85% by weight or higher). The maximum alkyl (meth)acrylate content is not particularly limited; it is preferably 95% by weight or lower (e.g. 90% by weight or lower).

Secondary monomers capable of introducing possible crosslinking points into the acrylic polymer or of enhancing the adhesive strength include hydroxy group-containing monomers, carboxy group-containing monomers, acid anhydride group-containing monomers, amide group-containing monomers, amino group-containing monomers, imide group-containing monomers, epoxy group-containing monomers, (meth)acryloylmorpholine, and vinyl ethers. Among them, hydroxy group-containing monomers and carboxy group-containing monomers are preferable. Hydroxy group-containing monomers are more preferable.

Favorable examples of the acrylic polymer in the art disclosed herein include an acrylic polymer in which a hydroxy group-containing monomer is copolymerized as the secondary monomer. Examples of the hydroxy group-containing monomer include hydroxyalkyl (meth)acrylates such as 2-hydroxyethyl (meth)acrylate, 2-hydroxypropyl (meth)acrylate, 3-hydroxypropyl (meth)acrylate, 2-hydroxybutyl (meth)acrylate, and 4-hydroxybutyl (meth)acrylate; polypropylene glycol mono(meth)acrylate; and N-hydroxyethyl(meth)acrylamide. Particularly preferable hydroxy group-containing monomers include a hydroxyalkyl (meth)acrylate having a linear alkyl group with two to four carbon atoms. In view of the hydrophobicity of the alkyl group, a hydroxyalkyl(meth)acrylate having a linear alkyl group with four carbon atoms.

Other examples include an acrylic polymer in which a carboxy group-containing monomer is copolymerized as the secondary monomer. Examples of the carboxy group-containing monomer include acrylic acid (AA), methacrylic acid (MAA), carboxyethyl (meth)acrylate, carboxypentyl (meth)acrylate, itaconic acid, maleic acid, fumaric acid, crotonic acid, and isocrotonic acid. Among them, AA and MAA are preferable.

As the secondary monomer, solely one species or a combination of two or more species can be used. When the monomers forming the acrylic polymer comprises a functional group-containing monomer, from the standpoint of the cohesive strength, etc., the ratio of the functional group-containing monomer in the monomers is suitably 0.1% by weight or higher, preferably 1% by weight or higher, or more preferably 3% by weight or higher. The upper limit is preferably 30% by weight or lower (e.g. 25% by weight or lower). The ratio of the hydroxy group-containing monomer to all the monomers is suitably about 2% by weight or higher, preferably 5% by weight or higher, more preferably 12% by weight or higher, or yet more preferably 16% by weight or higher. In view of the properties brought about by the primary monomer, the maximum ratio of the hydroxy group-containing monomer is suitably, for instance, 30% by weight or lower (typically 24% by weight or lower).

As the monomers forming the acrylic polymer, for a purpose such as increasing the cohesive strength of the acrylic polymer, other comonomers can be used besides the aforementioned secondary monomers. Examples of the comonomers include vinyl ester-based monomers such as vinyl acetate; aromatic vinyl compounds such as styrene; cycloalkyl (meth)acrylates such as cyclohexyl (meth)acrylate; aromatic ring-containing (meth)acrylates such as aryl (meth)acrylates; olefinic monomers such as ethylene, propylene, isoprene, butadiene and isobutylene; polyfunctional monomers such as 1,6-hexanediol di(meth)acrylate, having two or more (e.g. three or more) polymerizable functional groups (e.g. (meth)acryloyl groups) per molecule.

The amount of the other comonomers can be suitably selected in accordance to the purpose and application and is not particularly limited. It is preferably 10% by weight or less (e.g. 1% by weight or less) of the monomers.

The composition of the monomers forming the acrylic polymer is suitably designed so that the acrylic polymer has a glass transition temperature (Tg) in a prescribed range. Here, the Tg of the acrylic polymer refers to the value determined by the Fox equation based on the composition of the monomers. As shown below, the Fox equation is a relational expression between the Tg of a copolymer and glass transition temperatures Tgi of homopolymers of the respective monomers constituting the copolymer.

1/Tg=Σ(Wi/Tgi)

In the Fox equation, Tg represents the glass transition temperature (unit: K) of the copolymer, Wi the weight fraction (copolymerization ratio by weight) of a monomer i in the copolymer, and Tgi the glass transition temperature (unit: K) of homopolymer of the monomer i.

As the glass transition temperatures of homopolymers used for determining the Tg value, values found in publicly known documents are used. For instance, with respect to the monomers listed below, the following values are used as the glass transition temperatures of their homopolymers.

| | |
|---|---|
| 2-ethylhexyl acrylate | −70° C. |
| n-butyl acrylate | −55° C. |
| ethyl acrylate | −22° C. |
| lauryl acrylate | 0° C. |
| 2-hydroxyethyl acrylate | −15° C. |
| 4-hydroxybutyl acrylate | −40° C. |
| acrylic acid | 106° C. |
| methacrylic acid | 228° C. |

As for the glass transition temperatures of homopolymers of other monomers besides those exemplified above, the values given in “Polymer Handbook” (3rd edition, John Wiley & Sons, Inc., Year 1989) can be used. When the literature provides two or more values for a certain monomer, the highest value is used.

While no particular limitations are imposed, from the standpoint of the adhesion, the acrylic polymer's Tg is advantageously about 0° C. or lower, or preferably about −5° C. or lower (e.g. about −15° C. or lower, or −25° C. or lower). From the standpoint of the PSA layer's cohesive strength, the acrylic polymer's Tg is about −75° C. or higher, or preferably about −70° C. or higher (e.g. −50° C. or higher, or even −30° C. or higher). The acrylic polymer's Tg can be adjusted by suitably changing the monomer composition (i.e. the monomer species used for synthesizing the polymer and their ratio).

The acrylic polymer's Mw is not particularly limited. For instance, it can be about 10×10⁴ or higher and 500×10⁴ or lower. From the standpoint of the cohesion, the Mw is about 30×10⁴ or higher and suitably about 45×10⁴ or higher (e.g. about 65×10⁴ or higher). In a preferable embodiment, the acrylic polymer's Mw is 70×10⁴ or higher, more preferably about 90×10⁴ or higher, or yet more preferably about 110×10⁴ or higher. The Mw is suitably 300×10⁴ or lower (more preferably about 200×10⁴ or lower, e.g. about 150×10⁴ or lower).

It is noted that Mw is determined from a value obtained based on standard GPC by GPC. As the analyzer, for instance, model name HLC-8320 GPC (columns: TSKgel GMH-H(S) available from Tosoh Corporation) can be used.

The method for obtaining the acrylic polymer is not particularly limited. Various polymerization methods known as synthetic methods of acrylic polymers may be appropriately employed, such as solution polymerization, emulsion polymerization, bulk polymerization, suspension polymerization and photopolymerization. For instance, solution polymerization may be preferably employed. As the method for supplying the monomers when solution polymerization is carried out, all-at-once supply by which all starting monomers are supplied at once, continuous supply (addition), portion-wise supply (addition) and like method can be suitably employed. The polymerization temperature can be appropriately selected according to the species of monomers, solvent, and polymerization initiator used, etc. It can be, for instance, about 20° C. to 170° C. (typically about 40° C. to 140° C.). In a preferable embodiment, the polymerization temperature can be about 75° C. or lower (more preferably about 65° C. or lower, e.g. about 45° C. to 65° C.).

As the solvent (polymerization solvent) used for solution polymerization, a suitable solvent can be selected among heretofore known organic solvents. For instance, it is possible to use one kind of solvent or a mixture of two or more kinds of solvents, selected among aromatic compounds (aromatic hydrocarbons) such as toluene and xylene; acetic acid esters such as ethyl acetate; aliphatic or alicyclic hydrocarbons such as hexane; lower alcohols such as isopropanol; ketones; and the like.

The initiator used in the polymerization can be suitably selected among heretofore known polymerization initiators in accordance with the polymerization method. For instance, one, two or more species of azo-based polymerization initiator can be preferably used, such as 2,2′-azobisisobutylonitrile (AIBN). Other examples of polymerization initiator include peroxide-based initiators such as benzoyl peroxide (BPO) and hydrogen peroxide. Other polymerization initiators include persulfates such as potassium persulfate; substituted ethane-based initiators such as phenyl-substituted ethane; aromatic carbonyl compounds; and redox-based initiators by a combination of a peroxide and a reducing agent. Among these polymerization initiators, solely one species or a combination of two or more species can be used. The polymerization initiator can be used in a typical amount selected from a range of, for instance, about 0.005 part to 1 part (typically about 0.01 part to 1 part) by weight to 100 parts by weight of the monomers.

### (Blend of Acrylic Polymer and Rubber-Based Polymer)

The PSA layer according to an embodiment of the art disclosed herein is a rubber-acrylic blend PSA layer comprising a rubber-based polymer and an acrylic polymer as the base polymer. As the rubber-based polymer, one, two or more species can be used among the aforementioned rubber-based polymers. As the acrylic polymer, one, two or more species can be used among the aforementioned acrylic polymers. The rubber-based polymer and acrylic polymer can be suitably mixed together to preferably combine the rubber-based polymer's advantage (moisture resistance, etc.) and acrylic polymer's advantage (low level of outgassing, adhesive properties, etc.). When a rubber-based polymer and an acrylic polymer are used together, the weight ratio of rubber-based polymer (R) to acrylic polymer (A), R/A, can be, for instance, 95/5 to 20/80; it is preferably 90/10 to 30/70, more preferably 80/20 to 40/60, or yet more preferably 70/30 to 50/50.

In an embodiment using an acrylic polymer and a rubber-based polymer together as described above, because of their difference in molecular weight, it is possible to preferably bring about moisture resistance based on the lower molecular weight polymer as well as adhesive properties (cohesive strength, etc.) based on the higher molecular weight polymer. From such a standpoint, the ratio (M_{A}/M_{R}) of acrylic polymer's Mw (M_{AC}) to rubber polymer's Mw (M_{R}) is higher than 1, preferably about 3 or higher, more preferably about 5 or higher, or yet more preferably about 10 or higher (e.g. about 15 or higher). The maximum M_{AC}/M_{R} ratio value is suitably about 100 or lower, preferably about 50 or lower, more preferably about 30 or lower, or yet more preferably about 20 or lower. As for the Mw of the acrylic polymer used in the blend, a suitable range can be selected from the aforementioned Mw (ranges) of the acrylic polymer. As the Mw of the rubber-based polymer used in the blend, a suitable range can be selected from the aforementioned Mw (ranges) of the rubber-based polymer (the aforementioned Mw (ranges) of the isobutylene-based polymer, Mw (ranges) of polyisobutylene and Mw (ranges) of butyl rubber). The same is true with Mw/Mn.

### (Crosslinking Agent)

The PSA composition (preferably a solvent-based PSA composition) used for forming the PSA layer preferably comprises a crosslinking agent as an optional component. The PSA layer in the art disclosed herein may include the crosslinking agent in a post-crosslinking-reaction form, a pre-crosslinking-reaction form, a partially-crosslinked form, an intermediate or combined form of these, etc. In typical, the crosslinking agent is mostly included in the post-crosslinking-reaction form.

The type of crosslinking agent is not particularly limited. A suitable species can be selected and used among heretofore known crosslinking agents. Examples of the crosslinking agent include isocyanate-based crosslinking agents, epoxy-based crosslinking agents, oxazoline-based crosslinking agents, aziridine-based crosslinking agents, melamine-based crosslinking agents, carbodiimide-based crosslinking agents, hydrazine-based crosslinking agents, amine-based crosslinking agents, peroxide-based crosslinking agents, metal chelate-based crosslinking agents, metal alkoxide-based crosslinking agents, and metal salt-based crosslinking agents. For the crosslinking agent, solely one species or a combination of two or more species can be used. Examples of the crosslinking agent that can be preferably used in the art disclosed herein include isocyanate-based crosslinking agents and epoxy-based crosslinking agents. In particular, isocyanate-based crosslinking agents are more preferable.

As the isocyanate-based crosslinking agent, it is preferable to use a polyfunctional isocyanate (which refers to a compound having an average of two or more isocyanate groups per molecule, including a compound having an isocyanurate structure). For the isocyanate-based crosslinking agent, solely one species or a combination of two or more species can be used. Examples of preferable polyfunctional isocyanates include a polyfunctional isocyanate having an average of three or more isocyanate groups per molecule. Such a tri-functional or higher polyfunctional isocyanate can be a multimer (e.g. dimer or trimer), a derivative (e.g., an addition product of a polyol and two or more polyfunctional isocyanate molecules), a polymer of bi-functional or tri-functional isocyanate(s). Examples include polyfunctional isocyanates such as dimer and trimer of diphenylmethane diisocyanate, an isocyanurate (a cyclic trimer) of hexamethylene diisocyanate, product of reaction between trimethylolpropane and tolylene diisocyanate, product of reaction between trimethylolpropane and hexamethylene diisocyanate, polymethylene polyphenyl isocyanate, polyether polyisocyanate, and polyester polyisocyanate.

As the epoxy-based crosslinking agent, a compound having two or more epoxy groups per molecule can be used without particular limitations. A preferable epoxy-based crosslinking agent has three to five epoxy groups per molecule. For the epoxy-based crosslinking agent, solely one species or a combination of two or more species can be used. While no particular limitations are imposed, specific examples of the epoxy-based crosslinking agent include N,N,N′,N′-tetraglycidyl-m-xylenediamine, 1,3-bis(N,N-diglycidylaminomethyl)cyclohexane, 1,6-hexanediol diglycidyl ether, polyethylene glycol diglycidyl ether, and polyglycerol polyglycidyl ether.

The crosslinking agent content in the PSA composition disclosed herein is not particularly limited. From the standpoint of the cohesion, to 100 parts by weight of the base polymer (e.g. acrylic polymer), it is suitably about 0.001 part by weight or more, preferably about 0.002 part by weight or more, more preferably about 0.005 part by weight or more, or yet more preferably about 0.01 part by weight or more. From the standpoint of the adhesive strength and elastic modulus, the crosslinking agent content in the PSA composition is, to 100 parts by weight of the base polymer (e.g. acrylic polymer), about 20 parts by weight or less, suitably about 15 parts by weight or less, or preferably about 10 parts by weight or less (e.g. about 5 parts by weight or less).

In the embodiment using an isocyanate-based crosslinking agent, its amount used is not particularly limited. The isocyanate-based crosslinking agent can be used in an amount of, for instance, about 0.5 part by weight or more and about 10 parts by weight or less to 100 parts by weight of the base polymer (e.g. an acrylic polymer). From the standpoint of the cohesion, the amount of isocyanate-based crosslinking agent used to 100 parts by weight of the base polymer (e.g. an acrylic polymer) is suitably about 1 part by weight or more, or preferably about 1.5 parts by weight or more. The amount of isocyanate-based crosslinking agent used to 100 parts by weight of the base polymer (e.g. an acrylic polymer) is suitably about 8 parts by weight or less, or preferably about 5 parts by weight or less (e.g. about less than 4 parts by weight).

### (Other Additives)

The PSA composition may comprise, as necessary, various additives generally used in the PSA field, such as tackifier (tackifier resin), leveling agent, crosslinking accelerator, plasticizer, fillers, colorants including pigments and dyes, softening agent, anti-static agent, anti-aging agent, UV-absorbing agent, antioxidant and photo-stabilizing agent. With respect to these various additives, heretofore known species can be used by typical methods. In the art disclosed herein, the amount of outgassing from the PSA sheet is limited to or below a prescribed value. Thus, it is desirable to avoid using a low-molecular-weight component which may be susceptible to outgassing. From such a standpoint, the other additive content (e.g. tackifier resin) in the PSA layer is preferably limited to or below about 10% by weight (e.g. to or below 5% by weight, typically to or below 3% by weight). The art disclosed herein can be preferably implemented in an embodiment where the PSA layer is essentially free of other additives (e.g. tackifier resin).

The PSA layer can be formed based on a method for forming a PSA layer in a known PSA sheet. For example, it is preferable to use a method (direct method) where a PSA composition having PSA-layer-forming materials dissolved or dispersed in a suitable solvent is directly provided (typically applied) to a substrate (a moisture-impermeable layer) and allowed to dry to form a PSA layer. In another method (transfer method) that can be employed, the PSA composition is provided to a highly-releasable surface (e.g. a surface of a release liner, a substrate's back face that has been treated with release agent, etc.) and allowed to dry to form a PSA layer on the surface, and the PSA layer is transferred to a support substrate (a moisture-impermeable layer). As the release face, a surface of a release liner, a substrate's back face that has been treated with release agent, and the like can be used. The PSA layer disclosed herein is typically formed in a continuous manner.

The form of the PSA composition is not particularly limited. For instance, it can be in various forms, such as a PSA composition (a solvent-based PSA composition) that comprises PSA-layer-forming materials as described above in an organic solvent, a PSA composition (water-dispersed PSA composition, typically an aqueous emulsion-based PSA composition) in which the PSA is dispersed in an aqueous solvent, a PSA composition that is curable by an active energy ray (e.g. UV ray), and a hot-melt PSA composition. From the standpoint of the ease of application and the adhesive properties, a solvent-based PSA composition can be preferably used. As the solvent, it is possible to use one species of solvent or a mixture of two or more species, selected among aromatic compounds (typically aromatic hydrocarbons) such as toluene and xylene; acetic acid esters such as ethyl acetate and butyl acetate; and aliphatic or alicyclic hydrocarbons such as hexane, cyclohexane, heptane and methyl cyclohexane. While no particular limitations are imposed, it is usually suitable to adjust the solvent-based PSA composition to include 5% to 30% non-volatiles (NV) by weight. Too low an NV tends to result in higher production costs while too high an NV may degrade the handling properties such as the ease of application.

The PSA composition can be applied, for instance, with a known or commonly used coater such as gravure roll coater, reverse roll coater, kiss roll coater, dip roll coater, bar coater, knife coater, and spray coater.

In the art disclosed herein, the thickness of the PSA layer forming the adhesive face is not particularly limited. The PSA layer has a thickness of suitably 3 μm or greater, preferably 10 μm or greater, or more preferably 20 μm or greater. With increasing thickness of the PSA layer, the adhesive strength to adherend tends to increase. Having at least a certain thickness, the PSA layer absorbs the adherend's surface roughness to form tight adhesion. When the PSA layer has a thickness of 10 μm or greater, for instance, it can provide good, tight adhesion to an adherend having a surface whose arithmetic mean surface roughness Ra is about 1 μm to 5 μm (e.g. 3 μm). The thickness of the PSA layer forming the adhesive face can be, for instance, 150 μm or less; it is suitably 100 μm or less, or preferably 50 μm or less. With decreasing thickness of the PSA layer, it tends to show a greater ability to inhibit water vapor from laterally permeating the PSA layer, leading to reduction of outgassing from the PSA layer. A smaller thickness of the PSA layer is also advantageous from the standpoint of reducing the thickness and weight of the PSA sheet.

### (Properties of PSA Layer)

The storage modulus at 25° C., G′(25° C.), of the PSA layer disclosed herein is not particularly limited and it can be set in a suitable range according to required properties, etc. In a preferable embodiment, the G′(25° C.) is less than 0.5 MPa. The PSA layer whose G′(25° C.) is at or below a prescribed value wets the adherend surface well to form tight adhesion. The G′(25° C.) is more preferably 0.4 MPa or less, yet more preferably 0.3 MPa or less, or particularly preferably 0.25 MPa or less. The G′(25° C.) can also be, for instance, 0.2 MPa or less. The G′(25° C.) value is not particularly limited and is suitably greater than about 0.01 MPa, preferably 0.05 MPa or greater, or more preferably 0.07 MPa or greater (e.g. 0.1 MPa or greater).

The peak loss factor value of the PSA layer disclosed herein is not particularly limited and it can be set in a suitable range according to required properties, etc. In a preferable embodiment, from the standpoint of the damping properties (impact absorption), the peak loss factor value is 0.8 or greater. The peak loss factor value can also be 1.0 or greater, or even 1.2 or greater (e.g. 1.4 or greater). The upper limit of the peak loss factor value can be, for instance, 2.0 or less (typically 1.6 or less).

In the art disclosed herein, the storage modulus G′(25° C.) and the peak loss factor of a PSA layer can be determined by dynamic elastic modulus measurement. In particular, several layers of the PSA subject to measurement are layered to fabricate an approximately 2 mm thick PSA layer. A specimen obtained by punching out a disc of 7.9 mm diameter from the PSA layer is fixed between parallel plates. With a rheometer (e.g. ARES available from TA Instruments or a comparable system), dynamic elastic modulus measurement is carried out to determine storage modulus G′(25° C.) and the peak loss factor. The loss factor (tan δ) can be determined by the equation tan δ=G″/G′; and in the plot of temperature dependence thereof, the peak value is the peak loss factor. In the equation, G″ is a loss modulus. The PSA layer subject to measurement can be formed by applying a layer the corresponding PSA composition on a release face of a release liner or the like and allowing it to dry or cure. The thickness (coating thickness) of the PSA layer subjected to the measurement is not particularly limited as long as it is 2 mm or less. It can be, for instance, about 50 μm.

Measurement mode: shear mode

Temperature range: −50° C. to 150° C.

Heating rate: 5° C./min

Measurement frequency: 1 Hz

The same measurement method is also used in the working examples described later.

### <Moisture-Impermeable Layer>

With respect to the moisture-impermeable layer in the art disclosed herein, no particular limitations are imposed on the material and form of layering as long as the layer (film) has gas barrier properties. As used herein, the moisture-impermeable layer refers to a layer (film) that has a moisture permeability (a water vapor transmission rate in the thickness direction) of less than 5×10⁻¹ g/m² when determined over a 24-hour period at 40° C. at 90% RH based on the MOCON method (JIS K7129:2008). With the use of the moisture-impermeable layer satisfying this property, it is possible to obtain a PSA sheet having moisture resistance in the thickness direction. The moisture permeability is preferably less than 5×10⁻² g/m², or more preferably less than 5×10⁻³ g/m², for instance, less than 5×10⁻⁵ g/m². As the moisture permeability measurement device, PERMATRAN-W3/33 available from MOCON, Inc. or a comparable product can be used. It is noted that in the PSA sheet disclosed herein, the moisture-impermeable layer can be a substrate (support substrate) that supports the PSA layer.

In a preferable embodiment, the moisture-impermeable layer disclosed herein includes an inorganic layer. The material or structure of the inorganic layer is not particularly limited and can be selected in accordance of the purpose and usage. From the standpoint of the moisture resistance and air-tight properties, it is advantageous that the inorganic layer is essentially non-porous. In typical, a preferable inorganic layer is essentially formed of an inorganic material. For instance, an inorganic layer formed of at least 95% (by weight) inorganic material is preferable (more preferably at least 98% by weight, or yet more preferably at least 99% by weight). The number of inorganic layers in the moisture-impermeable layer is not particularly limited; it can be one, two or more (e.g. about two to five). From the standpoint of the ease of manufacturing and availability, the number of inorganic layers in the moisture-impermeable layer is preferably about 1 to 3, or more preferably one or two. When the moisture-impermeable layer includes several inorganic layers, the materials and structures (thicknesses, etc.) of these inorganic layers can be the same with or different from one another.

As the inorganic material forming the inorganic layer, it is possible to use, for instance, metal materials including elemental metals such as aluminum, copper, silver, iron, tin, nickel, cobalt, and chromium as well as alloys of these; and inorganic compounds such as oxides, nitrides and fluorides of metals and metalloids including silicon, aluminum, titanium, zirconium, tin and magnesium. Specific examples of the inorganic compounds include silicon oxides (SiOₓ, typically SiO₂), aluminum oxide (Al₂O₃), silicon nitride (Si₃N₄), silicon oxide nitride (SiOₓN_{y}), titanium oxide (TiO₂), and indium tin oxide (ITO).

The metal materials can be used as the inorganic layers as metal foils (e.g. aluminum foil) formed by a known method such as rolling by a rolling mill, etc. Alternatively, for instance, a metal material formed in a layer by a known film-forming method such as vacuum vapor deposition, spattering and plating.

The inorganic compound can be typically used as the inorganic layer in a form of thin film formed by a known method. As the method for forming thin film of the inorganic compound, various vapor deposition methods can be used. For instance, physical vapor deposition methods (PVD) such as vacuum vapor deposition, spattering and ion plating, chemical vapor deposition methods (CVD) and like method can be used. The moisture-impermeable layer may further have a resin layer on top of the vapor deposition layer. For instance, the resin layer may be a topcoat layer provided for purposes such as protecting the vapor deposition layer.

From the standpoint of the moisture resistance, ease of manufacturing, availability, etc., it is preferable to use an inorganic layer formed of, for instance, aluminum or an aluminum alloy. From the standpoint of the moisture resistance, ease of manufacturing, availability, etc., as the inorganic layer formed of an inorganic compound, for instance, a silicon oxide layer or an aluminum oxide layer can be preferably used. Examples of an inorganic layer preferable for being able to form a highly transparent inorganic layer include a silicon oxide layer, an aluminum oxide layer and an ITO layer.

The maximum thickness of the inorganic layer is not particularly limited. From the standpoint of obtaining conformability to shapes of adherends, the inorganic layer advantageously has a thickness of 50 μm or less. From the standpoint of reducing the thickness and weight of the PSA sheet, the thickness of the inorganic layer is suitably 15 μm or less, preferably 13 μm or less, more preferably 11 μm or less, or yet more preferably 9 μm or less. When the moisture-impermeable layer includes several inorganic layers, the combined thickness of these inorganic layers is in these ranges. The minimum thickness of the inorganic layer is not particularly limited and can be suitably selected so as to obtain a PSA sheet that shows moisture resistance suited for the purpose and usage. The thickness of the inorganic layer is suitably 1 nm or greater. From the standpoint of the moisture resistance, air-tight properties, etc., it is preferably 2 nm or greater, or more preferably 5 nm or greater. When the moisture-impermeable layer includes several inorganic layers, it is preferable that at least one of them has a thickness in these ranges. Each of the several inorganic layers may have a thickness in these ranges as well.

The preferable thickness range of the inorganic layer may also vary depending on the material of the inorganic layer, the formation method, etc. For instance, when metal foil (e.g. aluminum foil) forms the inorganic layer (or the metal layer), in view of the moisture resistance, ease of manufacturing, crease resistance, etc., its thickness is suitably 1 μm or greater, preferably 2 μm or greater, or more preferably 5 μm or greater. In view of the flexibility which leads to adherend conformability, the metal layer's thickness is suitably 50 μm or less, preferably 20 μm or less, more preferably 15 μm or less, yet more preferably 12 μm or less, or particularly preferably 10 μm or less. With respect to the inorganic layer formed by vapor deposition of an inorganic compound, in view of the balance between flexibility and ease of manufacturing the moisture-impermeable layer, its thickness is suitably in a range between 1 nm and 1000 nm, preferably in a range between 2 nm and 300 nm, or more preferably in a range between 5 nm and less than 100 nm.

The moisture-impermeable layer disclosed herein may include a resin layer in addition to the inorganic layer. The resin layer may serve as a protection layer to prevent the inorganic layer from getting damaged by bending deformation and friction. Thus, the moisture-impermeable layer including the resin layer in addition to the inorganic layer is preferable from the standpoint of the endurance and reliability of moisture-resistant properties and also from the standpoint of the ease of handling the moisture-impermeable layer or the PSA sheet. By placing the resin layer on the PSA layer side surface of the moisture-impermeable layer, the anchoring of the PSA layer can be enhanced. When the inorganic layer is formed by vapor deposition, spattering or like method, the resin layer can be used as the base for forming the inorganic layer.

The structure of the resin layer is not particularly limited. For instance, the resin layer may include a void space as in fiber assemblies such as woven fabrics and non-woven fabrics or as in foam bodies such as polyethylene foam; or it can be a resin layer (resin film) essentially free of a void space. From the standpoint of reducing the thickness of the PSA sheet, it is preferable use a resin layer essentially free of a void space.

As the resin material forming the resin layer, it is possible to use, for instance, polyester resins such as polyethylene terephthalate (PET), polybutylene terephthalate (PBT) and polyethylene naphthalate (PEN); polyolefin resins such as polyethylene (PE) and polypropylene (PP); polyimide (PI); polyetheretherketone (PEEK); chlorine-containing polymers such as polyvinyl chloride (PVC) and polyvinylidene chloride; polyamide-based resins such as nylon and aramid; polyurethane resin; polystyrene-based resin; acrylic resins; fluororesins; cellulose-based resins; and polycarbonate-based resins. Of these, solely one species or a combination of two or more species can be used. When two or more species of resin are used together, these resins can be used blended or separately. Both thermoplastic resins and thermosetting resins can be used. From the standpoint of the ease of forming film, etc., a thermoplastic resin is preferably used.

In the moisture-impermeable layer including a resin layer, at an edge face of the PSA sheet, water vapor may enter the resin layer from its side (lateral surface). From the standpoint of inhibiting such entrance of water vapor, as the resin material forming the resin layer, a highly moisture-resistant material can be preferably used. For instance, a preferable resin layer is formed, using a resin material whose primary component is a polyester resin such as PET or a polyolefinic resin such as PE and PP In a preferable embodiment, PET film can be preferably used as the resin layer. In another preferable embodiment, as the resin layer, it is preferable to use BOPP (biaxially oriented polypropylene) film obtainable by forming film of a resin material that comprises PP as the primary component and biaxially stretching the film. In the PSA sheet having no inorganic layer further on the adherend side relative to the resin layer, it is particularly significant to inhibit entrance of water vapor from the lateral surface of the resin layer. A typical example of the PSA sheet having such a constitution is a PSA sheet in which the PSA layer-side surface of the moisture-impermeable layer is formed with a resin layer.

The resin layer may include, as necessary, various additives such as fillers (inorganic fillers, organic fillers, etc.), anti-aging agent, antioxidant, UV absorber, anti-static agent, slip agent and plasticizer. The ratio of the various additives included is below about 30% by weight (e.g. below 20% by weight, typically below 10% by weight).

The number of resin layers in the moisture-impermeable layer is not particularly limited and it can be one, two or more (e.g. about two to five). From the standpoint of the ease of manufacturing and availability, the number of resin layers in the moisture-impermeable layer is preferably one to three, or more preferably one or two. When the moisture-impermeable layer includes several resin layers, the materials and structures (thicknesses, inclusion of a void space, etc.) of these resin layers can be the same with or different from one another.

The method for forming the resin layer is not particularly limited. A heretofore known general resin film molding method can be suitably employed to form the resin layer, for instance, extrusion molding, inflation molding, T-die casting, calender roll molding and wet casting. The resin layer may a non-stretched kind or may be subjected to a stretching process such as uni-axial stretching and bi-axial stretching.

The minimum thickness of the resin layer is not particularly limited. From the standpoint of the crease resistance, ease of forming film, etc., the thickness of the resin layer is suitably 1 μm or greater, preferably 3 μm or greater, more preferably 5 μm or greater, or yet more preferably 7 μm or greater. When the moisture-impermeable layer includes several resin layers, it is preferable that at least one of them has a thickness in these ranges. Each of the several resin layers may have a thickness in these ranges as well.

The maximum thickness of the resin layer is not particularly limited. For instance, it can be 100 μm or less. From the standpoint of reducing the thickness and weight of the PSA sheet, the thickness of the resin layer is suitably 70 μm or less, preferably 55 μm or less, or more preferably 35 μm or less. When the moisture-impermeable layer includes several resin layers, the combined thickness of these resin layers is preferably in these ranges. In general, the moisture permeability of the resin layer is higher than that of the inorganic layer. Thus, it is also preferable to make the combined thickness of resin layers smaller from the standpoint of preventing water vapor from entering the resin layer from its lateral surface.

The inorganic layer and the resin layer are preferably bonded. The bonding method is not particularly limited. A method known in the pertinent field can be suitably employed. For instance, it is possible to employ a method (extrusion lamination) where a resin material for forming the resin layer is melted and extruded along with a pre-molded inorganic layer (typically metal foil), a method where a solution or dispersion of the resin material for forming the resin layer is applied to a pre-molded inorganic layer and allowed to dry, and like method. Alternatively, it is also possible to employ a method where an inorganic layer is vapor-deposited on a pre-molded resin layer, a method where an inorganic layer is bonded to a separately-molded resin layer, and like method. For instance, the bonding can be achieved by hot pressing. The resin layer and the inorganic layer can be bonded via an adhesive layer or a PSA layer.

The adhesive layer to bond the resin layer and the inorganic layer can be an undercoat layer formed by applying an undercoat such as primer to the resin layer. As the undercoat, those known in the pertinent field can be used, such as urethane-based undercoat, ester-based undercoat, acrylic undercoat, and isocyanate-based undercoat. From the standpoint of reducing the thickness and weight of the PSA sheet, the thickness of the undercoat layer is suitably 7 μm or less, preferably 5 μm or less, or more preferably 3 μm or less. The minimum thickness of the undercoat layer is not particularly limited. For instance, it can be 0.01 μm or greater (typically 0.1 μm or greater).

Before the bonding process, the resin layer may be subjected to common surface treatment, chemical or physical treatment, for instance, mattifying treatment, corona discharge treatment, crosslinking treatment, chromic acid treatment, ozone exposure, flame exposure, high-voltage electric shock exposure, and ionized radiation treatment.

The PSA layer(s) placed between layers forming the moisture-impermeable layer to bond them together are not exposed to the surface of the PSA sheet; and therefore, they do not correspond to the PSA layer forming the adhesive face of the PSA sheet. In the PSA sheet disclosed herein, the material and physical properties of such a PSA layer for internal use in the moisture-impermeable layer are not particularly limited. The PSA layer can be formed of a PSA similar to the PSA layer forming the adhesive face or can be formed of a different PSA. It is not particularly limited in thickness, either. For instance, it may have a comparable thickness to the undercoat layer.

Favorable examples of the moisture-impermeable layer used in the PSA sheet disclosed herein include a moisture-impermeable layer formed of a laminate body that comprises an inorganic layer as well as first and second resin layers laminated on top and bottom of the inorganic layer. The first and second resin layers forming the moisture-impermeable layer are laminated on top and bottom of the inorganic layer. As long as such a layer order can be obtained, the first and second resin layers may be in direct contact with the inorganic layer or they may be placed via undercoat layers as described above to obtain tight adhesion between themselves and the inorganic layer. In the PSA sheet disclosed herein, the first resin layer refers to the resin layer placed on the backside (the front face of the moisture-impermeable layer) of the PSA sheet relative to the inorganic layer and the second resin layer refers to the resin layer placed on the PSA layer side.

The inorganic layer can be a metal layer formed of an aforementioned metal material. For instance, an aluminum layer is preferable. The first and second resin layers are preferably formed from the same material. For instance, thermoplastic resins exemplified above can be used. Of these materials, solely one species or a combination of two or more species can be used. Each of the first and second resin layers may have a layered structure with two or more layers, but is preferably a monolayer. In particular, preferable materials forming the first and second resin layers include PET, PP and polystyrene. PET and PP are more preferable.

The first and second resin layers have thicknesses T_{R1} and T_{R2}, respectively and their ratio (T_{R1}/T_{R2}) is not particularly limited, but is suitably 0.5 or greater, preferably 1 or greater, more preferably 1.5 or greater, or yet more preferably 2.0 or greater. The T_{R1}/T_{R2} ratio is suitably about 10 or less, preferably 7.0 or less, more preferably 5.0 or less, or yet more preferably 4.0 or less. When the T_{R1}/T_{R2} ratio is in these ranges, adherend conformability and crease resistance can be preferably combined. The thickness T_{R1} of the first resin layer is suitably about 10 μm or greater, preferably 15 μm or greater, more preferably 18 μm or greater, or yet more preferably 20 μm or greater (e.g. 22 μm or greater). T_{R1} is suitably about 100 μm or less, preferably 70 μm or less, more preferably 60 μm or less, yet more preferably 50 μm or less, or particularly preferably 35 μm or less. The thickness T_{R2} of the second resin layer is suitably about 1 μm or greater, preferably 3 μm or greater, more preferably 5 μm or greater, or yet more preferably 7 μm or greater. T_{R2} is suitably about 25 μm or less, preferably 20 μm or less, more preferably 15 μm or less, or yet more preferably 12 μm or less (e.g. 10 μm or less).

The inorganic layer has a thickness T_{I} and the first and second resin layers have a combined thickness T_{R} (=T_{R1}+T_{R2}); and their ratio (T_{R}/T_{I}) is not particularly limited. From the standpoint of preventing creases, protecting the inorganic layer, etc., the ratio is suitably 1 or greater, preferably 2 or greater, more preferably 3 or greater, or yet more preferably 4 or greater. When it is bent and applied to accommodate the adherend shape, in view of the adherend conformability, the T_{R}/T_{I} ratio is suitably 10 or less, preferably 8 or less, or more preferably 6 or less. The total (T_{R}) of the first and second resin layers' thicknesses T_{R1} and T_{R2} is suitably about 15 μm or greater, preferably 20 μm or greater, more preferably 25 μm or greater, or yet more preferably 30 μm or greater. T_{R} is suitably about 100 μm or less, preferably 80 μm or less, more preferably 70 μm or less, or yet more preferably 60 μm or less (e.g. 50 μm or less). The moisture-impermeable layer in this embodiment can effectively protect the inorganic layer (e.g. an aluminum layer) as thin film from bending, creasing, breaking, etc. By this, even when the PSA sheet is exposed to various stressors in the manufacturing process, etc., or even when it is exposed to a harsh environment for a long period while in use, it can securely maintain the properties as the moisture-resistant film.

As the method for forming a laminate body having the inorganic layer, first resin layer and second resin layer, it is possible to employ various methods as described earlier, such as a method where the respective layers are formed as films by a known method and they are laminated dry by forming undercoat layers described above, a method where the inorganic layer is formed on the first resin layer in a tightly bonded manner and the second resin layer is laminated dry or extrusion-laminated on top of it, and like method.

The minimum thickness of the moisture-impermeable layer is not particularly limited. From the standpoint of the ease of manufacturing and handling the PSA sheet, the thickness of the moisture-impermeable layer is about 3 μm or greater, or suitably about 5 μm or greater (e.g. 10 μm or greater). To obtain moisture resistance and rigidity unsusceptible to creasing, it is desirable that the moisture-impermeable layer is thick. From such a standpoint, the thickness of the moisture-impermeable layer is preferably 15 μm or greater, more preferably 20 μm or greater, yet more preferably 30 μm or greater, or particularly preferably 40 μm or greater. The maximum thickness of the moisture-impermeable layer is not particularly limited, either. It is about 1 mm or less, or suitably about 300 μm or less (e.g. 150 μm or less). From the standpoint of the adherend conformability of the PSA sheet and of reducing its thickness and weight, the thickness of the moisture-impermeable layer is preferably 100 μm or less, more preferably 80 μm or less, yet more preferably 70 μm or less, or particularly preferably 65 μm or less (e.g. 55 μm or less). The moisture-impermeable layer with such a limited thickness is less likely to lead to formation of a space between the adherend and the PSA sheet; and therefore, it can prevent water vapor permeation through the space.

The PSA layer-side surface of the moisture-impermeable layer may be subjected to common surface treatment, chemical or physical treatment, for instance, mattifying treatment, corona discharge treatment, crosslinking treatment, chromic acid treatment, ozone exposure, flame exposure, high-voltage electric shock exposure, and ionized radiation treatment. On the PSA layer-side surface of the moisture-impermeable layer, an undercoat layer may be placed, which is formed by applying an undercoat such as primer to the resin layer. As the undercoat, those known in the pertinent field can be used, such as urethane-based, ester-based, acrylic, and isocyanate-based kinds. From the standpoint of reducing the thickness and weight of the PSA sheet, the thickness of the undercoat layer is suitably 7 μm or less, preferably 5 μm or less, or more preferably 3 μm or less.

### <Release Liner>

In the art disclosed herein, a release liner can be used during formation of the PSA layer; fabrication of the PSA sheet; storage, distribution and shape machining of the PSA sheet prior to use, etc. The release liner is not particularly limited. For example, a release liner having a release layer on the surface of a liner substrate such as resin film and paper; a release liner formed from a low adhesive material such as a fluoropolymer (polytetrafluoroethylene, etc.) or a polyolefinic resin (PE, PP, etc.); or the like can be used. The release layer can be formed, for instance, by subjecting the liner substrate to a surface treatment with a release agent such as a silicone-based, long-chain alkyl-based, fluorine-based, or molybdenum disulfide-based release agent. When the PSA sheet is used as a sealing material for a magnetic disc device, it is preferable to use a non-silicone-based release liner free of a silicone-based release agent which may produce siloxane gas.

### <Applications>

The PSA sheet disclosed herein has excellent moisture resistance with reduced gas emission; and therefore, it is preferably used in various applications where entry of moisture and gas is desirably limited. For instance, the PSA sheet disclosed herein is preferably used for sealing the internal space of a magnetic disc device such as HDD. In this application, an included gas such as siloxane gas may cause damage to the device; and therefore, it is important to prevent such gas contamination. In a magnetic disc device employing HAMR, it is important to prevent entrance of water which badly affects the recording life. By using the PSA sheet disclosed herein as a sealing material (or a cover seal) for a HAMR magnetic disc device, a magnetic recording device having a higher density can be obtained.

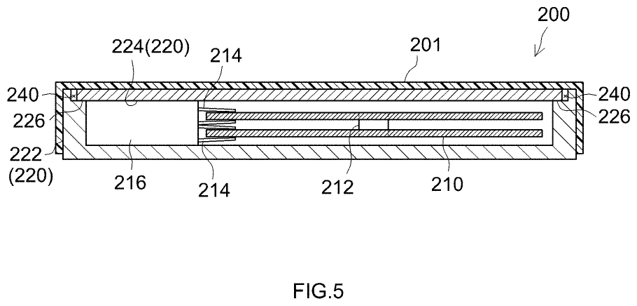

FIG. 4 shows an embodiment of the magnetic disc device as a favorable example to which the art disclosed herein can be applied. FIG. 4 shows a cross-sectional diagram schematically illustrating the magnetic disc device according to an embodiment. A magnetic disc device 100 comprises a data-recording magnetic disc 110, a spindle motor 112 that rotates magnetic disc 110, a magnetic head 114 that reads and writes data on magnetic disc 110, and an actuator 116 that supplies power to magnetic head 114. Actuator 116 has a built-in linear motor not shown in the drawing. In this example of constitution, two magnetic discs 110 are included, but it is not limited to this and three or more magnetic discs may be included.

These components of magnetic disc device 100 are placed in a housing 120 which serves as a casing for magnetic disc device 100. In particular, the components of magnetic disc device 100 are contained in a box-shaped housing base member (a support structure) 122 having a top opening and the top opening of housing base member 122 is covered with a rigid cover member 124. More specifically, the top opening of housing base member 122 has a recessed portion around the inner circumference and the outer rim of cover member 124 is placed on the bottom of recessed portion 126, with cover member 124 covering the opening. A PSA sheet 101 is applied from the top face of cover member 124 so as to entirely cover the cover member 124 and the top face (outer circumference of the opening) of housing 120, that is, the entire top face of housing 120, altogether. This seals a space 140 present between housing base member 122 and cover member 124 as well as other holes and void spaces that communicate from the inside to the outside of magnetic disc device 100, thereby keeping the inside of the device air-tight. Such a sealing structure using PSA sheet 101 as the sealing material (cover seal) can be made thinner than a conventional counterpart that uses a cover member and a gasket to obtain air-tight properties. In addition, because it does not require the use of a liquid gasket, outgassing from the gasket can be eliminated as well. In this embodiment, the width of the top rim (face of the frame) of housing base member 122 is about 0.1 mm to 5 mm (e.g. 3 mm or less, or even 2 mm or less) at its narrowest portion, with the width being the distance between the outer circumference and inner circumference of the top rim of housing base member 122. When PSA sheet 101 is applied as a cover seal to the top face of housing base member 122, the top rim of housing base member 122 provides a bonding surface to PSA sheet 101, forming a portion that isolates the internal space of magnetic disc device 100 from the outside. According to the art disclosed herein, even in an application where the width of bonding surface (through-bonding-plane permeation distance) is limited, the internal space can be maintained air-tightly and dry (moisture-resistant).

FIG. 5 shows another embodiment of the magnetic disc device to which the art disclosed herein can be applied. A magnetic disc device 200 has basically the same constitution as the embodiment described above except for the way a PSA sheet 201 is applied. Different features are described below. In magnetic disc device 200, PSA sheet 201 covers cover member 224 and the top face (outer circumference of the opening) of housing base member 222 altogether, having a margin (or an extending portion) that further extends to the side of housing 220. In particular, the extending portion is bent from the top face over the corner of top rim to the side of housing base member 222. The extending portion may be provided entirely or partially at each side forming the outer circumference of the top face of housing 220. In other words, in magnetic disc device 200, PSA sheet 201 is applied, at least partially covering the top and side faces of housing 220 in a U shape. Similar to PSA sheet 101 according to the embodiment described above, PSA sheet 201 seals a space 240 present between housing base member 222 and cover member 224 as well as other holes and void spaces that communicate from the inside to the outside of magnetic disc device 200; and because it is applied with a margin extending to the side of housing base member 222, the sealed state is extended in the in-plane directions of bonding interface. This results in a larger distance (width) of the bonding interface of PSA sheet 201 separating the outside and space 240, etc., and it inhibits moisture permeation via the bonding interface of PSA sheet 201, thereby further enhancing the moisture resistance. In this embodiment, the distance of PSA sheet 201 extending from the top rim (top edge of the side) to the side of housing 220 (i.e. the length of PSA sheet 201 that covers the side (lateral surface)) is about 1 mm or greater (e.g. 2 mm or greater, or even 3 mm or greater).

In these embodiments, cover members 124 and 224 cover magnetic discs 110 and 210 as well as actuators 116 and 216 altogether, respectively, in one piece. However, they are not limited to these. They may cover magnetic discs 110 and 210, actuators 116 and 216, and other components, separately; or they may not cover actuators 116 or 216 while covering magnetic discs 110 and 210. Even in these embodiments, by applying the PSA sheet over the cover member, the inside of the device can be made moisture-resistant and air-tight. In a magnetic disc device having such an embodiment, the moisture resistance and air-tight properties are obtained with the thin PSA sheet, thereby achieving a thin sealing structure. This can increase the capacity for housing magnetic discs, bringing about a magnetic disc device having a higher density and a larger capacity

As described above, the art disclosed herein provides a magnetic disc device. It may provide not only the magnetic disc device, but also an electronic part casing capable of housing an electronic part whether or not it includes an electronic part such as a magnetic disc. The electronic part casing may have an aforementioned embodiment. For instance, the electronic part casing disclosed herein may have an encasing member having an opening, and a closing member attached to the encasing member to close the opening. A low-pressure or inert gas space is formed inside the encasing member and an electronic part can be housed in the space. A sealing member is provided to a location between the closing member and the encasing member where the opening of the encasing member is sealed or provided onto the outside of the closing member. The sealing member is a sheet body having a periphery and it is placed between the encasing member and the closing member or placed on the outside of the closing member. As the sealing member, the sheet body disclosed herein can be used.

The sealing member is preferably bonded to the encasing member and/or to the closing member, with a 180° peel strength of 3 N/20 mm or greater. As for the conditions of the 180° peel strength measurement, the sealing member is used as the measurement object and the encasing member and/or the closing member with the sealing member adhered thereon are used as the adherend(s); otherwise, the same peel conditions as the to-SUS 180° peel strength measurement for the PSA sheet described earlier are basically applied. It is noted that, in general, the material forming the electronic part casing (e.g. an HDD case) including the encasing member and the closing member can be stainless steel (SUS304, etc.) or an aluminum material with bisphenol A epoxy resin coated by cationic electrodeposition. The sealing member may bond to an adherend formed of such a material, with at least the prescribed adhesive strength.

### <Moisture Permeability Measurement Method for PSA Sheet>

The moisture permeability measurement method for PSA sheet in the art disclosed herein comprises (A) a step of obtaining a metal plate having an opening; (B) a step of preparing a measurement sample by adhering a PSA sheet to the metal plate to cover the opening; (C) a step of placing the measurement sample between a dry chamber and a wet chamber in a moisture permeability measurement device; and (D) a step of quantifying moisture permeation using the moisture permeability measurement device to determine the moisture permeability of the PSA sheet from the measured value. This method enables previously impossible, highly precise quantification of moisture permeation in an in-plane direction.

In the method above, in the step (A), a metal plate having an opening is obtained. The peripheral length of the opening of the metal plate corresponds to the bonding length of the bonding interface with the PSA sheet. The peripheral length (bonding length L) of the opening in the metal plate is not particularly limited. It is suitably 10 mm or greater. From the standpoint of quantifying a minute amount of moisture permeation precisely and consistently, it is preferably 100 mm or greater, more preferably 150 mm or greater, or yet more preferably 180 mm or greater. The opening's maximum peripheral length is not particularly limited. In view of the size of the measurement device, etc., it is suitably 1000 mm or less, preferably 500 mm or less, more preferably 300 mm or less, or yet more preferably 250 mm or less (specifically 220 mm or less). The peripheral shape of the metal plate's opening is not particularly limited. It can be a circle, oval, triangle, quadrangle, pentagon or higher polygon. In particular, circles, triangles and quadrangles (squares, rectangles, trapezoids, parallelograms, rhomboids) are preferable; and squares, rectangles and rhomboids are more preferable. In a particularly preferable embodiment, the metal plate's opening has a square shape with side length about 50 mm (i.e. about 200 mm in peripheral length of opening). In FIG. 3, a metal plate 56 having a square opening 58 is shown as a suitable example.

The type of metal plate is not particularly limited. For instance, an aluminum plate can be used. As the metal plate, a stainless steel plate or a copper plate can be used as well. The size and thickness of the metal plate can be suitably selected to suit the moisture permeability measurement device. In view of readily obtaining tight adhesion with the PSA sheet, the metal plate preferably has at least a certain level of rigidity and suitably has a thickness of, for instance, greater than 0.1 mm, or preferably about 0.2 mm to 0.4 mm (typically about 0.3 mm). From the standpoint of the ease of processing (forming an opening), etc., the metal plate preferably has a thickness of less than 0.5 mm. In view of tight adhesion with the PSA sheet, the metal plate preferably has a smooth surface (at least the surface of where the PSA sheet is adhered). For instance, a preferable metal plate can have an arithmetic mean roughness Ra of about 3 μm or less. As the metal plate, it is possible to use, for instance, an 100 mm by 100 mm, 0.3 mm thick aluminum (e.g. A1050) plate that has a surface with Ra of 3 μm or less and has an opening at the center.

In the step (B), a measurement sample is prepared by adhering a PSA sheet to the metal plate to cover the opening of the metal plate. The PSA sheet is typically, but not limited to, an adhesively single-faced PSA sheet having a moisture-impermeable layer as a substrate. It can be a substrate-supported double-faced PSA sheet; a substrate-free double-faced PSA sheet; or a substrate-supported, single-faced or double-faced PSA sheet having a moisture-permeable substrate. In such a case, on one face of the PSA sheet, a moisture-impermeable layer such as metal film can be laminated to prepare a measurement sample. Because the PSA sheet needs to cover the opening of the metal plate, it preferably has a shape equivalent (comparable) to, but larger than the opening. In typical, the PSA sheet has the same shape as the metal plate's opening and has a larger size than the opening by as much as the bonding width (permeation distance) W. This makes it possible to obtain a mostly constant bonding width (permeation distance) W for the bonding interface between the PSA sheet and the metal plate. FIG. 3 shows a measurement sample 60 in which a square PSA sheet 1 is adhered across a square opening 58. When the bonding width of the PSA sheet is not constant relative to the metal plate's opening, the bonding width can be randomly measured at several locations (e.g. at least 4 locations, preferably at least 10 locations) and their average can be used as the bonding width (average bonding width). From the standpoint of precise measurement of moisture permeation, the bonding width W is suitably 1 mm or greater, preferably 2 mm or greater, more preferably 2.5 mm or greater; and the bonding width W is suitably 10 mm or less, preferably 5 mm or less, or more preferably 3 mm or less. The PSA sheet can be adhered to the metal plate to allow tight adhesion between the two and no other limitations are imposed in particular. For instance, for preferable adhesion, a roller (about 1 kg to 2 kg roller) is rolled back and forth once or twice over the backside of the PSA sheet placed on the metal plate, covering the opening.

While no particular limitations are imposed, in order to make the bonding width (permeation distance) of the PSA sheet from the metal plate's opening uniform over the entire bonding length (peripheral length of the opening in the metal plate), it is preferable to use a positioning tool (guide) when adhering the PSA sheet to the metal plate. As the positioning tool, for instance, it is preferable to use a transparent plate that has marks for where the PSA sheet should be fixed and has one weakly adhesive face. Along the marks of the positioning tool, the PSA sheet is placed with the backside (possibly a non-adhesive face, substrate-side surface, moisture-impermeable surface) on the positioning tool side and the PSA sheet is temporarily fixed with the weak adhesiveness of the transparent plate's surface. By this, the PSA sheet's backside is temporarily fixed to the weakly adhesive surface of the positioning tool. In particular, the positioning tool with the positioning marks and one weakly adhesive face is placed flat with the weakly adhesive face up; and over this, the PSA sheet is placed with the backside down along the marks of the positioning tool. By this, the PSA sheet is temporarily fixed to the positioning tool. Further on top of this, the metal plate is layered, whereby the PSA sheet bonds to the peripheries of the metal plate's opening. Preferably, when the adhesive face of the PSA sheet is protected with a release liner, after the PSA sheet's backside is temporarily fixed to the positioning tool, the release liner is removed to expose the adhesive face of the PSA sheet and the metal plate is adhered thereto. As the transparent plate forming the positioning tool, for instance, a commercial transparent resin plate (e.g. a transparent acrylic plate) can be used. The transparent plate can be made weakly adhesive, for instance, by adhering a commercial weakly adhesive double-faced tape to one face of the transparent plate. From the standpoint of the ease of positioning, it is preferable that the positioning tool and the metal plate have the same outer shape.

From the standpoint of the precision of the measurement, at the bonding interface between the PSA sheet and the metal plate, the ratio (W/L) of the bonding width W (permeation distance) to the bonding length L (peripheral length of metal plate's opening) preferably satisfies 1/10 or lower, more preferably 1/50 or lower, or yet more preferably 1/100 or lower. The minimum W/L ratio is not particularly limited and it is suitably 1/1000 or higher, for instance, 1/500 or higher.

In the step (C), the measurement sample is placated between a dry chamber and a wet chamber of a moisture permeability measurement device. FIG. 2 shows a constitutional example of the measurement device. Reference signs 50 shows a moisture permeability measurement device, 54 a dry chamber, 52 a wet chamber, and 60 a measurement sample. As shown in the drawing, measurement sample 60 can be placed with PSA sheet 1 either on the wet chamber 52 side or on the dry chamber 54 side. In moisture permeability measurement device 50, measurement sample 60 is preferably placed with PSA sheet 1 on the wet chamber 52 side in accordance with the application of PSA sheet 1 (e.g. when used as a sealing member to moisture-proof the inner space of a magnetic disc device). The measurement device is not particularly limited. A heretofore known or conventionally used moisture permeability measurement device can be used. A preferable moisture permeability measurement device conforms to JIS K 7129:2008. Suitable examples include measurement device PERMATRAN-W3/34G available from MOCON Inc., and comparable products. The wet chamber suitably has an RH of 70% or higher (preferably 80% to 100%, typically 90% 5%). The dry chamber suitably has an RH below 5% (preferably below 1%, typically about 0%).

In the step (D), moisture permeation is quantified using the moisture permeability measurement device to determine the moisture permeability of the PSA sheet from the measured value. In particular, the moisture permeability determined here is the moisture permeability in in-plane direction of bonding interface of the PSA sheet. The moisture permeability measurement is not particularly limited. It is preferably carried out according to Method B of JIS K 7129:2008, or more preferably based on a MOCON method (equal-pressure method). For the balance between the precision of quantification and the efficiency, the measurement time is preferably 1 hour or more (e.g. 12 hours or more, more preferably 24 hours or more) and preferably 1 week or less (e.g. 3 days or less, preferably 1 day or less). In a typical embodiment, the measurement time is 3 hours to 9 hours (e.g. 5 hours to 7 hours, preferably about 6 hours). The internal temperature is preferably kept constant in the range between 10° C. and 80° C. (e.g. 10° C. to 40° C., typically 40° C.). While no particular limitations are imposed, from the standpoint of carrying out more precise measurement, it is preferable to carry out quantification of moisture permeation after conditioning for a certain time period under the same conditions as the moisture permeability measurement. The conditioning time is suitably about 1 hour or more, or preferably about 2 hours or more (e.g. about 3 hours).

There are no particular limitations as to how the resulting measurement value is used. For instance, the division of moisture permeation by area of bonding interface of the PSA sheet can be used as the moisture permeability. This is because the area of bonding interface is thought to have a negative proportional relationship to moisture permeation. The area of bonding interface of the PSA sheet is determined as the product of permeation distance (bonding width) W and bonding length L. The moisture permeability is preferably determined from the moisture permeation per 24-hour period obtained by converting the measurement time to 24 hours. This facilitates comparison among samples with varied measurement time. In particular, the 24-hour moisture permeation obtained from the measured value and the PSA layer's surface area (permeation distance×bonding length) are substituted into the equation:

Moisture permeability (μg/cm²·24 h)=moisture permeation (μg)/(permeation distance (cm)×bonding length (cm)×24 hours)

to determine the moisture permeability in in-plane direction of bonding interface (μg/cm²·24 h).

It is noted that the moisture permeability (μg/cm²·24 h) can be synonymous with the moisture permeability (μg/cm²) as a property of the PSA sheet which is determined from the 24-hour moisture permeation and the PSA sheet's bonding area (permeation distance×bonding length)

Other favorable conditions related to the measurement are as described with respect to the properties of the PSA sheet; and therefore, redundant details are omitted here.

### <Permeability Measurement Method for PSA Sheet>

The permeability measurement method for PSA sheet in the art disclosed herein comprises (A) a step of obtaining a metal plate having an opening; (B) a step of preparing a measurement sample by adhering a PSA sheet to the metal plate to cover the opening; (C) a step of placing the measurement sample between a dry chamber and a wet chamber in a permeability measurement device; and (D) a step of allowing an eluent (typically prescribed gas, e.g. helium gas) to enter (typically to flow in) the first or second chamber, measuring the amount of the eluent passed through the measurement sample, and determining, from the measured value, the permeability of the eluent in the PSA sheet. This method enables previously impossible, highly precise quantification of permeation in an in-plane direction.

In the permeability measurement method, the steps (A) and (B) are basically the same as the moisture permeability measurement method. Thus, redundant details are omitted. As for the steps (C) and (D), the water vapor is changed to a different eluent (typically a prescribed gas, e.g. helium gas), but the rest is basically the same as the moisture permeability measurement method. For instance, when using helium gas as the eluent, one chamber is filled with helium gas to a prescribed pressure and any helium gas moved to the other chamber is quantified with a detector such as helium gas detector to determine the permeability.

Other favorable conditions related to the measurement are as described with respect to the moisture permeability measurement method; and therefore, redundant details are omitted here.

### <Moisture Permeability Measurement Device>

The art disclosed herein also provides a moisture permeability measurement device. The moisture permeability measurement device is preferably used to quantify moisture permeation of a PSA sheet (in particular, moisture permeation in in-plane direction of bonding interface of a PSA sheet). The moisture permeability measurement device disclosed herein has a first chamber, a second chamber and a partition plate placed between the first chamber and the second chamber. The first chamber may be in continuation or in communication with the second chamber before the partition plate is placed. The partition plate has an opening that communicates between the first and second chambers. A measurement object (typically a PSA sheet) is adhered to cover the opening of the partition plate to determine the moisture permeability.

FIG. 2 outlines an embodiment of the moisture permeability measurement device with an attached measurement object. In moisture permeability measurement device 50, reference signs 52, 54 and 56 represent the first chamber, the second chamber and the partition plate, respectively; and the measurement object (PSA sheet 1 here) is positioned to cover opening 58 of partition plate 56. In the embodiment shown in the drawing, first chamber 52 is a wet chamber and second chamber 54 is a dry chamber, but it is not limited to this embodiment. As long as one of first chamber 52 and second chamber 54 is a wet chamber and the other a dry chamber, moisture permeability can be measured. The RH and internal temperatures of the wet and dry chambers are as described in the moisture permeability measurement method. Thus, redundant details are omitted.

The partition plate is typically, but not limited to, a metal plate. As long as precise measurement of moisture permeability is ensured, it is possible to use a plate formed from a moisture-impermeable material, such as a resin plate having an inorganic layer (e.g. a metal layer). The same applies to the aforementioned moisture permeability measurement method. Favorable examples of the partition plate include the metal plates used in the moisture permeability measurement method. With respect to the partition plate, except at the opening, moisture permeation needs to be prevented or sufficiently limited in the thickness direction. The plate part suitably has a moisture permeability (a water vapor permeation rate in thickness direction) of less than 5×10⁻¹ g/m², determined, for instance, based on a MOCON method (JIS K 7129:2008), at 40° C. and 90% RH, over a 24-hour period. The moisture permeability is preferably less than 5×10⁻² g/m², or more preferably less than 5×10⁻³ g/m²·24 h, for instance, less than 5×10⁻⁵ g/m². As the moisture permeability measurement device, PERMATRAN-W3/34G available from MOCON, Inc. or a comparable product can be used.

In a typical embodiment, a PSA sheet as a measurement object is adhered to cover the opening of the partition plate to carry out measurement. FIG. 3 shows an example of a specific constitution. Partition plate 56 with adhered PSA sheet 1 shown in FIG. 3 can be detachably set for each measurement object (PSA sheet 1, here); and therefore, it is referred to as a measurement sample 60 for convenience. Details (e.g. specifics of adhesion of PSA sheet 1) of the measurement sample 60 are as described in the moisture permeability measurement method. Thus, redundant descriptions are omitted. Likewise, for other features (size, thickness, Ra, opening's shape and size) of the partition plate, the features of the metal plate used in the moisture permeability measurement method can be applied, not limited to the metal plate. Thus, redundant details are omitted. As described above, the partition plate disclosed herein is used as a test instrument for moisture permeability measurement. Accordingly, the art disclosed herein provides a test used for measuring the moisture permeability in in-plane direction of bonding interface of a PSA sheet. The test instrument has a plate part having an opening as a member corresponding to the partition plate, but otherwise is not limited in particular. For instance, in order to enable its setting in the moisture permeability measurement device, it may have other part(s) besides the plate part. The matters (features, constitution, etc.) related to the test instrument are the same as the description regarding the partition plate. Thus, details are not repeated.

The moisture permeability measurement device disclosed herein may have a moisture (water vapor concentration) detecting means such as infrared sensor (shown by reference sign IR in FIG. 2) and a gas supply means to maintain the partitioned first and second chambers under equal pressure. The gas supply means may supply dry N₂ gas (e.g. at 0% RH) to the dry chamber and wet N₂ gas (e.g. at 90% RH) to the wet chamber. Other features of the moisture permeability measurement device can be suitably selected based on common technical knowledge of a skilled person and do not characterize the art disclosed herein. Thus, details are omitted.

The embodiment having wet and dry chambers as described above can be designed and fabricated based on conventionally known art or can be obtained by suitably modifying a known or commonly used moisture permeability measurement device (e.g. a commercial product). While no particular limitations are imposed, except for the partition plate and related parts, a commercial moisture permeability measurement device can be used. Examples of such commercial measurement devices include product name PERMATRAN-W3/34G available from MOCON Inc., and comparable products.

### <Permeability Measurement Device>

The art disclosed herein also provides a permeability measurement device. The permeability measurement device is preferably used to quantify permeation of a PSA sheet (in particular, permeation of an eluent (typically a gas, e.g. helium gas) in in-plane direction of bonding interface of a PSA sheet). The permeability measurement device disclosed herein has a first chamber, a second chamber and a partition plate placed between the first chamber and the second chamber. The first chamber may be in continuation or in communication with the second chamber before the partition plate is placed. The partition plate has an opening that communicates between the first and second chambers. A measurement object (typically a PSA sheet) is adhered to cover the opening of the partition plate to determine the moisture permeability. It is noted that excluding the water vapor which is changed to a different eluent (typically a prescribed gas, e.g. helium gas), all characteristics such as the constitution, structure, shape and materials used of the permeability measurement device are basically the same as those of the moisture permeability measurement device. Thus, redundant descriptions are not repeated. For instance, when using helium gas as the eluent, the device may have a gas-filling means to fill one chamber with helium gas to a prescribed pressure. The device may also have a detector such as helium gas detector to detect any helium gas moved to the other chamber.

Other features of the permeability measurement device can be suitably selected based on common technical knowledge of a skilled person and do not characterize the art disclosed herein. Thus, details are omitted.

Matters disclosed by this description include the following:

(1) A magnetic disc device comprising

at least one data-recording magnetic disc,

a motor that rotates the magnetic disc,

a magnetic head that at least either reads or writes data on the magnetic disc,

an actuator that moves the magnetic head, and

a housing that encases the magnetic disc, the motor, the magnetic head and the actuator; wherein

the housing is provided with a cover seal, the cover seal being a PSA sheet comprising a PSA layer, and

the PSA sheet has a moisture permeability of less than 90 μg/cm² in in-plane direction of bonding interface of the PSA sheet, determined based on a MOCON method, at a permeation distance of 2.5 mm over a 24-hour period; and has an amount of thermally release gas of 10 μg/cm² or less, determined at 130° C. for 30 minutes by gas chromatography/mass spectrometry.

(2) The magnetic disc device according to (1) above, wherein the housing comprises a box-shaped housing base member having a top opening and a cover member to cover the opening.
(3) The magnetic disc device according to (2) above, wherein the housing base member has a recessed portion around the inner circumference of the top opening and the outer rim of the cover member is placed on the bottom of the recessed portion.
(4) The magnetic disc device according to any of (1) to (3) above, wherein the cover member has a hole.
(5) The magnetic disc device according to any of (1) to (4) above, wherein the PSA sheet seals the internal space of the magnetic disc device.
(6) The magnetic disc device according to any of (1) to (5) above, wherein the PSA sheet covers and seals the top face of the housing base member of the magnetic disc device.
(7) The magnetic disc device according to any of (1) to (6) above, capable of heat-assisted magnetic recording.
(8) The magnetic disc device according to any of (1) to (7) above, wherein the PSA layer has a storage modulus below 0.5 MPa at 25° C.
(9) The magnetic disc device according to any of (1) to (8) above, wherein the PSA layer is a rubber-based PSA layer comprising a rubber-based polymer as its base polymer, an acrylic PSA layer comprising an acrylic polymer as its base polymer, or a rubber-acrylic blend PSA layer comprising a rubber-based polymer and an acrylic polymer as its base polymers.
(10) The magnetic disc device according to (9) above, wherein the PSA layer is the rubber-based PSA layer, wherein at least one species of monomer selected from the group consisting of butene, isobutylene and isoprene is polymerized in the rubber-based polymer
(11) The magnetic disc device according to any of (1) to (9) above, wherein the cover seal has a moisture-impermeable layer and the PSA layer is provided on one face of the moisture-impermeable layer.
(12) A PSA sheet having a PSA layer, wherein

the PSA sheet has a moisture permeability of less than 90 μg/cm² in in-plane direction of bonding interface of PSA sheet, measured based on the MOCON method, at a permeation distance of 2.5 mm over a 24 hour-period; and has an amount of thermally released gas of 10 μg/cm² or less, determined at 130° C. for 30 minutes by gas chromatography/mass spectrometry.

(13) A laminate sheet having a PSA layer on at least one face, wherein

based on a modified MOCON method, at a temperature of 40° C., through a 2.5 mm permeation distance in an in-plane direction (length in the width direction) of bonding interface of the PSA layer, the laminate sheet has a moisture permeability of gas at 90% relative humidity per 24-hour measurement period per unit bonding area (cm²) (or a 24-hour moisture permeation/PSA bonding area) of less than 90 μg/cm²·24 h; and

the laminate sheet has an amount of thermally released gas of 10 μg/cm² or less, measured at 130° C., over 30 minutes, by gas chromatography/mass spectrometry.

(14) The PSA sheet or the laminate sheet according to (12) or (13) above, having a 180 peel strength to stainless steel plate of 3 N/20 mm or greater.
(15) The PSA sheet or the laminate sheet according to any of (12) to (14), wherein the PSA layer has a storage modulus less than 0.5 MPa at 25° C.
(16) The PSA sheet or the laminate sheet according to any of (12) to (15) above, showing a displacement less than 2 mm in a shear holding power test carried out with a 1 kg load at 60° C. for one hour.
(17) The PSA sheet or the laminate sheet according to any of (12) to (16) above, wherein the PSA layer is a rubber-based PSA layer comprising a rubber-based polymer, an acrylic PSA layer comprising an acrylic polymer, or a rubber-acrylate blend PSA layer obtainable by blending a rubber-based polymer and an acrylic polymer.
(18) The PSA sheet or the laminate sheet according to (17) above, wherein

the PSA layer is the rubber-based PSA layer; and

in the rubber-based polymer, at least one species of monomer selected from the group consisting of butene, isobutylene and isoprene is polymerized.

(19) The PSA sheet or the laminate sheet according to (17) or (18) above, wherein

the rubber-based PSA layer comprises a rubber-based polymer A and a rubber-based polymer B;

in the rubber-based polymer A, isobutylene is polymerized, accounting for at least 50% (by weight) thereof and

in the rubber-based polymer B, isobutylene and isoprene are copolymerized.

(20) The PSA sheet or the laminate sheet according to any of (12) to (19) above, having a moisture-impermeable layer and the PSA layer is provided on one face of the moisture-impermeable layer.
(21) The PSA sheet or the laminate sheet according to any of (12) to (20) above, having a tensile modulus per unit width above 1000 N/cm and below 3500 N/cm.
(22) The PSA sheet or the laminate sheet according to any of (12) to (21) above, having a total thickness of 25 μm to 200 μm.
(23) The PSA sheet or the laminate sheet according to any of (12) to (22) above, comprises an inorganic layer.
(24) The PSA sheet or the laminate sheet according to (23) above, wherein the inorganic layer is a metal layer.
(25) The PSA sheet or the laminate sheet according to (23) or (24) above, wherein the inorganic layer is formed of aluminum or an aluminum alloy.
(26) The PSA sheet or the laminate sheet according to any of (23) to (25) above, wherein the inorganic layer has a thickness of 2 μm to 20 μm.
(27) The PSA sheet or the laminate sheet according to any of (23) to (26) above, wherein the gas barrier layer comprises a resin layer in addition to the inorganic layer.
(28) The PSA sheet or the laminate sheet according to (27) above, wherein the resin layer is a polyester resin layer.
(29) The PSA sheet or the laminate sheet according to (27) or (28) above, wherein the resin layer has a thickness of 3 μm to 55 μm.
(30) The PSA sheet or the laminate sheet according to any of (23) to (29) above, wherein the gas barrier layer is formed of a laminate comprising an inorganic layer as well as first and second resin layers laminated atop and below the inorganic layer.
(31) The PSA sheet or the laminate sheet according to any of (12) to (30) above, used for sealing the internal space of a magnetic disc device.
(32) A release liner-supported PSA sheet or laminate sheet comprising the PSA sheet or the laminate sheet according to any of (12) to (31) above and a release liner protecting the adhesive face of the PSA sheet or the laminate sheet, wherein the release liner is a non-silicone-based release liner free of a silicone-based release agent.
(33) An electronic part casing having the PSA sheet or the laminate sheet according to any of (12) to (31) above.
(34) A magnetic disc device having the PSA sheet or the laminate sheet according to any of (12) to (31) above.
(35) The magnetic disc device according to (34) above, wherein the PSA sheet or the laminate sheet seals the internal space of the magnetic disc device.
(36) The magnetic disc device according to (34) or (35) above, wherein the magnetic disc device has a housing base member and the PSA sheet or the laminate sheet is a cover seal that covers and seals the top face of the housing base member.
(37) The magnetic disc device according to any of (34) to (36) above, capable of heat-assisted magnetic recording.
(38) A method for measuring moisture permeability of PSA sheet, the method comprising
(A) a step of obtaining a metal plate having an opening;
(B) a step of preparing a measurement sample by adhering a PSA sheet to the metal plate to cover the opening;
(C) a step of placing the measurement sample between a dry chamber and a wet chamber of a moisture permeability measurement device; and
(D) a step of measuring moisture permeation using the moisture permeability measurement device and determining, from the measured value, the moisture permeability of the PSA sheet.
(39) A method for measuring permeability of PSA sheet, the method comprising
(A) a step of obtaining a metal plate having an opening;
(B) a step of preparing a measurement sample by adhering a PSA sheet to the metal plate to cover the opening;
(C) a step of placing the measurement sample between a first chamber and a second chamber of a permeability measurement device; and
(D) a step of allowing an eluent (typically prescribed gas, e.g. helium gas) to enter (typically to flow in) the first or second chamber, measuring the amount of the eluent passed through the measurement sample, and determining, from the measured value, the permeability of the eluent in the PSA sheet.
(40) The method according to (38) or (39) above, wherein, the PSA sheet and the metal plate has a bonding interface with a bonding length L (peripheral length of the opening in the metal plate) and a bonding width W (permeation distance) at a W/L ratio of 1/10 or below.
(41) The method according to (40) above, wherein the bonding length L is 100 mm or greater.
(42) The method according to (40) or (41) above, wherein the bonding width W is 1 mm to 10 mm.
(43) The method according to any of (38) to (42) above, wherein the metal plate's opening has a circle, triangle, or quadrangle peripheral shape.
(44) The method according to any of (38) to (43) above, wherein the metal plate's opening has a square, rectangle, or rhomboid peripheral shape.
(45) The method according to any of (38) to (44) above, wherein the moisture permeability measurement is carried out based on a MOCON method (equal-pressure method).
(46) A moisture permeability measurement device having a first chamber, a second chamber, and a partition plate placed between the first chamber and the second chamber; and the partition plate has an opening communicating between the first chamber and the second chamber.
(47) A permeability measurement device having a first chamber, a second chamber, and a partition plate placed between the first chamber and the second chamber; and the partition plate has an opening communicating between the first chamber and the second chamber.
(48) The apparatus according to (46) or (47) above, wherein, between the first chamber and the second chamber, one has a relative humidity of 70% or higher and the other has a relative humidity below 5%.
(49) The apparatus according to any of (46) to (48) above, wherein the partition plate is a metal plate.
(50) The apparatus according to (46) to (49) above, wherein a PSA sheet as a measurement object is adhered to the partition plate to cover the opening.
(51) The apparatus according to any of (46) to (50) above, having a bonding width W (a distance from a periphery (side) of the PSA sheet to the opening) of 1 mm to 10 mm.
(52) The apparatus according to any of (46) to (51) above, wherein the partition plate's opening has a circle, triangle, or quadrangle peripheral shape.
(53) The apparatus according to any of (46) to (52) above, wherein the partition plate's opening has a square, rectangle, or rhomboid peripheral shape.
(54) The apparatus according to any of (46) to (53) above, wherein the opening has a peripheral length of 100 mm or greater.
(55) A test instrument used for measuring the permeability or moisture permeability in in-plane direction of bonding interface of a PSA sheet, the instrument having a plate member having an opening.
(56) The test instrument according to (55) above, wherein the plate member is a metal plate.
(57) The test instrument according to (55) or (56) above, wherein a PSA sheet as a measurement object is adhered to the plate member to cover the opening.
(58) The test instrument according to any of (55) to (57) above, having a bonding width W (a distance from a periphery (side) of the PSA sheet to the opening) of 1 mm to 10 mm.
(59) The test instrument according to any of (55) to (58) above, wherein the opening has a circle, triangle, or quadrangle peripheral shape.
(60) The test instrument according to (55) to (59) above, wherein the opening has a square, rectangle, or rhomboid peripheral shape.
(61) The test instrument according to any of (55) to (60) above, wherein the opening has a peripheral length of 100 mm or greater.

Several working examples related to the present invention are described below, but the present invention is not intended to be limited to these examples. In the description below, “parts” and “%” are by weight unless otherwise specified.

### <Materials Used>

### [Rubber-Based Polymers]

PIB-A: polyisobutylene available from BASF Corporation, product name Oppanol N50, Mw˜34×10⁴, Mw/Mn 5.0

PIB-B: polyisobutylene available from BASF Corporation, product name Oppanol N80, Mw˜75×10⁴, Mw/Mn 5.0

PIB-C: polyisobutylene available from BASF Corporation, product name Oppanol B15, Mw˜7.5×10⁴, Mw/Mn 5.0

IIR: butyl rubber available from JSR Corporation, product name JSR BUTYL 268, Mw˜54×10⁴, Mw/Mn˜4.5

SIPS-A: hydrogenated styrene-isoprene-styrene block copolymer available Soken Chemical and Engineering Co., Ltd., product name 2563NS, Mw˜24×10⁴, Mw/Mn˜2.0, 11% styrene

SIPS-B: a blend of 25 parts each of product name Kraton D1161 (styrene-isoprene-styrene block copolymer, 15% styrene) and product name Kraton D1113 (styrene-isoprene-styrene block copolymer, 16% styrene) available from Kraton Corporation as base polymers as well as product name Regalite R1090 (hydrogenated hydrocarbon-based resin) available from EASTMAN and product name Escorez 2203 (aliphatic aromatic petroleum resin) available from ExxonMobil Chemical

SIS: PSA (rubber-based PSA whose primary component is SIS, 10% styrene) used in PSA tape VR5300 available from Nitto Denko Corporation

### [Acrylic Polymer]

### (Preparation of Acrylic Polymer A)

Using 95 parts of n-butyl acrylate (BA) and 5 parts of acrylic acid (AA) as monomers, ethyl acetate as polymerization solvent and 0.1 part of AIBN as polymerization initiator, solution polymerization was carried out by a typical method to obtain a solution (25% NV) of acrylic polymer A having a weight average molecular weight (Mw) of 130×10⁴. To this polymer solution, per 100 parts of acrylic polymer A, was added 2 parts (based on non-volatiles) of isocyanate-based crosslinking agent (product name CORONATE L, 75% ethyl acetate solution of trimethylolpropane-tolylene diisocyanate trimer adduct, available from Tosoh Corporation) to obtain a solution of acrylic PSA composition A.

### (Preparation of Acrylic Polymers B to H)

Using BA, octyl acrylate (OA), lauryl acrylate (LA), ethyl acrylate (EA), 4-hydroxybutyl acrylate (4HBA) and AA as monomers, in the same manner as the preparation of acrylic polymer A, were prepared acrylic polymers B to H having the monomer compositions shown in Table 2. T these, were added isocyanate-based crosslinking agent to obtain solutions of acrylic PSA compositions B to H.

### [Moisture-Impermeable Layer]

By dry bonding lamination, were laminated 25 μm thick PET film (PET layer) as the first resin layer, 7 μm thick aluminum foil (Al layer) as the inorganic layer and 9 μm thick PET film (PET layer) as the second resin layer in this order from the front (outer surface side) to the backside (PSA layer side). Between each resin layer and the inorganic layer, was laminated a 3 μm thick adhesive layer. A 47 μm thick moisture-impermeable layer was thus prepared.

### Example 1

In toluene, was dissolved PIB-A as the base polymer to prepare a PSA composition with 25% NV. The PSA composition obtained above was applied to one face (the second resin layer-side surface) of the moisture-impermeable layer to have a thickness of 30 μm after dried, and allowed to dry at 120° C. for 3 minutes to form a PSA layer. A PSA sheet was thus obtained according to this Example. For protection of the surface (adhesive face) of the PSA layer, was used a release liner formed of thermoplastic film treated with release agent (product name HP-S0 available from Fujico Co., Ltd.; 50 μm thick).

### Example 2 to Example 9

As the base polymers, in place of PIB-A, were used the following: IIR (Ex. 2), a 1:1 mixture of PIB-A and IIR (Ex. 3), a 1:1 mixture of PIB-B and IIR (Ex. 4), a 1:1 mixture of PIB-C and IIR (Ex. 5), a mixture of PIB-C and the solution of acrylic PSA composition A at 1:1 ratio of PIB-C to acrylic polymer A based on non-volatiles (Ex. 6), and SIPS-A (Ex. 7). As the PSA, were used SIPS-B (Ex. 8) and SIS (Ex. 9). Otherwise, in the same manner as Example, were obtained PSA sheets according to the respective Examples.

### Example 10 to Example 16

Were used acrylic PSA composition solutions B to H to form PSA layers. Otherwise in the same manner as Example 1, were obtained PSA sheets according to Examples 10 to 16.

### [Moisture Permeability (Cup Method) of PSA Layer]

The moisture permeability in the thickness direction of each PSA layer was determined based on the water vapor permeability test (cup method) in JIS Z 0208. In particular, the PSA composition was applied to a releasable surface and allowed to dry to form a 50 μm thick PSA layer. The PSA layer was adhered to 2 μm thick PET film (DIAFOIL available from Mitsubishi Plastics, Inc.) with a rubber roller. The PET layer-supported PSA layer was cut to a circle of 30 mm diameter to fit the diameter of the test cup (an aluminum cup of 30 mm diameter used in the cup method of JIS Z 0208). This was used as a test sample. A prescribed amount of calcium chloride was placed in the cup and the opening of the cup was sealed with the test sample prepared above. The cup covered with the test sample was placed in a thermostat wet chamber at 60° C. and 90% RH and left standing for 24 hours. The change in weight of calcium chloride before and after this step was determined to obtain the moisture permeability (g/cm²·24 h).

For each Example, Tables 1 and 2 show the species of PSA as well as the test results of moisture permeability (cup method) (g/cm²-24 h), storage moduli G′(25° C.) (MPa), through-bonding-plane moisture permeability of PSA sheet (μg/cm²), adhesive strength (N/20 mm), shear holding power (mm), amount of thermally released gas (μg/cm²), HDD adhesive strength (N/20 mm) and peak loss factor value.

TABLE 1

| | Ex. 1 | Ex. 2 | Ex. 3 | Ex. 4 | Ex. 5 | Ex. 6 | Ex. 7 | Ex. 8 | Ex. 9 |
|---|---|---|---|---|---|---|---|---|---|
| PSA species | FIB | HR | PIB/IIR | PIB/IIR | PIB/IIR | Acryl/PIB | SIPS | SIPS | SIS |
| PSA layer's elastic modules @25° C. (MPa) | 0.3 | 0.3 | 0.2 | 0.2 | 0.2 | 0.1 | 0.1 | 0.1 | 0.2 |
| Moisture permeability (cup method) (g/cm · 24 h) | 1.3 | 1.3 | 1.3 | 1.3 | 1.3 | 5.0 | 1.4 | 1.3 | 1.8 |
| Moisture permeability in in-plane direction | 28 | 30 | 7 | 10 | 5 | 44 | 22 | 13 | 14 |
| of bonding interface (μg/cm²) | | | | | | | | | |
| Adhesive strength (N/20 mm) | 6 | 3 | 11 | 6 | 13 | 13 | 10 | 21 | 28 |
| Shear holding power (mm) | 0.3 | 0.2 | 0.5 | 0.2 | 0.5 | 0.3 | 0.3 | 0.4 | 0.3 |
| Amount of thermally released gas (μg/cm²) | 0.8 | 0.8 | 0.8 | 0.8 | 0.8 | 0.6 | 11.5 | 15.3 | 10.5 |
| HDD adhesive strength (N/20 mm) | 7 | 5 | 7 | 3 | 8 | 9 | 10 | 14 | 22 |
| Peak loss factor | 1.65 | 1.55 | 1.55 | 1.55 | 1.55 | 1.2 | 1.4 | 1.4 | 1.5 |

TABLE 2

| | Ex. 10 | Ex. 11 | Ex. 12 | Ex, 13 | Ex. 14 | Ex. 15 | Ex. 16 |
|---|---|---|---|---|---|---|---|
| PSA species | Acryl B | Acryl C | Acryl D | Acryl E | Acryl F | Acryl G | Acryl H |
| Monomer composition (parts) | BA(80) | OA(80) | LA(80) | LA(95) | EA(80) | EA(95; | BA(93) |
| | 4HBA(20) | 4HBA(20) | 4HBA(20) | AA(5) | 4HBA(20) | AA(5) | AA(7) |
| PSA layer's elastic modules (MPa) | 0.05 | 0.09 | 0.12 | 0.13 | 0.07 | 0.09 | 0.09 |
| Moisture permeability (cup method) (g/cm · 24 h) | 8.8 | 4.7 | 4.2 | 4.2 | 10.3 | 13.3 | 12.3 |
| Moisture permeability in in-plane direction | 86 | 80 | 78 | 84 | 108 | 116 | 100 |
| of bonding interface (μg/cm²) | | | | | | | |
| Adhesive strength (N/20 mm) | 10 | 9 | 8 | 9 | 8 | 9 | 11 |
| Shear holding power (mm) | 0.1 | 0.1 | 0.1 | 0.1 | 0.1 | 0.1 | 0.1 |
| Amount of thermally released gas (μg/cm²) | 0.4 | 0.4 | 0.4 | 0.4 | 0.4 | 0.4 | 0.4 |
| HDD adhesive strength (N/20 mm) | 5 | 5 | 5 | 7 | 6 | 7 | 9 |
| Peak loss factor | 0.9 | 0.9 | 0.9 | 1.0 | 0.9 | 1.0 | 1.1 |

As shown in Tables 1 and 2, the PSA sheets according to Examples 1 to 6 and 10 to 13 had moisture permeability in in-plane direction of bonding interface of less than 90 μg/cm² as well as amounts of thermally released gas of 10 μg/cm². On the other hand, in Examples 7 to 9 and 14 to 16, either the moisture permeability in in-plane direction of bonding interface was not less than 90 μg/cm² or the amount of thermally released gas was above 10 μg/cm².

With respect to rubber-based PSA, Examples 1 to 9 all had excellent moisture resistance, but Examples 7 to 9 using styrene-containing polymers had a tendency to thermally release more gas. Good results were obtained in Examples using polyisobutylene and/or butyl rubber as the rubber-based PSA. Among them, Examples 3 to 5 using both polyisobutylene and butyl rubber exhibited significantly lower moisture permeability in in-plane direction of bonding interface although when tested by the cup method, no differences were observed from Examples 1 and 2 using a single rubber-based polymer. This suggests that the novel moisture permeability testing method concerning moisture permeability in in-plane direction of bonding interface allows precise evaluation of the influence of moisture permeation in a more minute amount; and it also demonstrates that the combined use of polyisobutylene and butyl rubber is effective in enhancing moisture resistance. From the results of Example 6, these rubber-based polymers can be used in combination with acrylic polymers. It is noted that in the evaluation of adhesive strength, Example 8 showed leftover adhesive residue after peeled off.

Acrylic PSA had a tendency to show higher moisture permeability than rubber-based PSA. From the results of Examples 10 to 12 and 14, it was found that the higher the number of carbon atoms was in the alkyl group of alkyl (meth)acrylate as a primary monomer, the greater the moisture resistance was. Among the compositions using carboxy group-containing monomers such as AA, Example 13 using lauryl acrylate as the primary monomer showed satisfactory moisture resistance. PSA using 4HBA as a functional group-containing monomer showed greater moisture resistance than PSA using AA. Examples using acrylic PSA all had low amounts of thermally released gas and exhibited excellent adhesive properties including shear holding power.

Although specific embodiments of the present invention have been described in detail above, these are merely for illustrations and do not limit the scope of claims. The art according to the claims includes various modifications and changes made to the specific embodiments illustrated above.

### REFERENCE SIGNS LIST

1, 101, 201 PSA sheets
10 moisture-impermeable layer
12 first resin layer
14 inorganic layer
16 second resin layer
20 PSA layer
50 moisture permeability measurement device
52 wet chamber (first chamber)
54 dry chamber (second chamber)
56 metal plate (partition plate)
58 opening
60 measurement sample
100, 200 magnetic disc devices
110,210 magnetic discs
112,212 spindle motors
114,214 magnetic heads
116,216 actuator
120,220 housing
122,222 housing base member
124,224 cover member
126,226 recessed portions
140,240 spaces

1. A laminate sheet body having a pressure-sensitive adhesive layer on at least one face, wherein
the sheet body has a moisture permeability of less than 90 μg/cm² per 24 hour measurement period in in-plane direction of bonding interface of the pressure-sensitive adhesive layer, obtained based on a modified MOCON method by carrying out measurement at a permeation cell temperature of 40° C., with humidistat gas at a temperature of 40° C. and 90% relative humidity supplied to a wet chamber, with the sheet body having an internal volume (bulk) forming a permeation channel that has a prescribed length of 2.5 mm; and
the sheet body has an amount of thermally released gas of 10 μg/cm² or less, measured at 130° C., over a 30-minute period, by gas chromatography/mass spectrometry.

2. The sheet body according to claim 1, exhibiting a 180° peel strength of 3 N/20 mm or greater to a stainless steel plate, determined based on JIS Z 0237:2009.

3. The sheet body according to claim 1, wherein the pressure-sensitive adhesive layer has a storage modulus below 0.5 MPa at 25° C. when the pressure-sensitive adhesive layer has a thickness of 2 mm, placed between two flat plates and subjected to viscoelasticity measurement.

4. The sheet body according to claim 1, showing a displacement less than 2 mm in a shear holding power test carried out with a 1 kg load at 60° C. for one hour.

5. The sheet body according to claim 1, wherein the pressure-sensitive adhesive layer has a thickness of 3 μm or greater and 100 μm or less.

6. The sheet body according to claim 1, having a tensile modulus greater than 1000 N/cm and less than 3500 N/cm in a tensile test at an inter-chuck distance of 20 mm, at a speed of 50 mm/min.

7. The sheet body according to claim 1, wherein the pressure-sensitive adhesive layer preferably has a peak loss factor of 0.8 or greater.

8. The sheet body according to claim 1, wherein the pressure-sensitive adhesive layer is a rubber-based pressure-sensitive adhesive layer comprising a rubber-based polymer, an acrylic pressure-sensitive adhesive layer comprising an acrylic polymer, or a rubber-acrylic blend pressure-sensitive adhesive layer comprising a rubber-based polymer and an acrylic polymer.

9. The sheet body according to claim 8, wherein the pressure-sensitive adhesive layer is the rubber-based pressure-sensitive adhesive layer, wherein at least one species of monomer selected from the group consisting of butene, isobutylene and isoprene is polymerized in the rubber-based polymer.

10. The sheet body according to claim 8, wherein
the rubber-based pressure-sensitive adhesive layer comprises a rubber-based polymer A and a rubber-based polymer B,
in the rubber-based polymer A, isobutylene is polymerized, accounting for at least 50% by weight thereof, and
in the rubber-based polymer B, isobutylene and isoprene are copolymerized.

11. A method for testing moisture permeation proceeding from a periphery of a sheet body having peripheries through the sheet body's internal volume via its surface to the outside, the method characterized by
using a permeation cell comprising a test piece-loading plate that has an opening in a location away from its peripheries with the plate partitioning the cell interior into a wet chamber and a dry chamber; and
placing the sheet body as a test piece on the test piece-loading plate, with the sheet body located where the distance along the sheet body between the sheet body's periphery and the opening of the test piece-loading plate forms a permeation channel of a prescribed length through the internal volume (bulk) of the sheet body, and the sheet body facing the wet chamber; supplying humidistat gas at prescribed temperature and relative humidity and dry gas to the wet chamber and to the dry chamber, respectively, under designated conditions; and detecting the relative humidity of emission gas released from the dry chamber.

12. A method for testing moisture permeation from a periphery of a sheet body having peripheries through the sheet body's internal volume via its surface to the outside, the method characterized by
using a permeation cell comprising a test piece-loading plate that has an opening in a location away from its peripheries, with the plate partitioning the interior into a wet chamber and a dry chamber; and
placing the sheet body as a test piece on the test piece-loading plate, with the sheet body located where the distance along the sheet body between the sheet body's periphery and the opening of the test piece-loading plate forms a permeation channel of a prescribed length through the internal volume (bulk) of the sheet body, and the sheet body facing the wet chamber; placing a moisture-impermeable layer on top of the sheet body; supplying humidistat gas at prescribed temperature and relative humidity and dry gas to the wet chamber and to the dry chamber, respectively, under designated conditions; and detecting the relative humidity of emission gas released from the dry chamber.

13. A method for the measuring moisture permeability of a sheet body that comprises a moisture-impermeable layer and a pressure-sensitive adhesive layer laminated on a surface of the moisture-impermeable layer and that has a periphery, with respect to permeation proceeding from the periphery of the sheet body in an in-plane direction through the sheet body's internal volume (bulk), based on a modified MOCON method, the method characterized by comprising:
adhering the pressure-sensitive adhesive layer with the sheet body covering an opening in a test piece-loading plate to form a permeation channel of 2.5 mm through the sheet body's internal volume (bulk); and
measuring the permeability of the sheet body based on a modified MOCON method.

14. An apparatus for testing moisture permeation from a periphery (or an edge face) of a sheet body having peripheries through the sheet body's internal volume via its surface to the outside, the apparatus characterized by
having
a permeation cell that comprises a test piece-loading plate having an opening in a location away from its peripheries (or edge faces) with the plate partitioning the interior into a wet chamber and a dry chamber,
a humidistat gas supply system that supplies humidistat gas at prescribed temperature and relative humidity to the dry chamber,
a dry gas supply system that supplies dry gas to the dry chamber, and
a humidity sensor connected to the dry chamber to detect the gas temperature inside the dry chamber; and
having a constitution in which the sheet body as a test piece is placed on the test piece-loading plate, with the sheet body located where the distance along the sheet body between the sheet body's periphery and the opening of the test piece-loading plate forms a permeation channel of a prescribed length through the internal volume (bulk) of the sheet body, the sheet body facing the wet chamber; and the relative humidity of emission gas released from the dry chamber is detected.

15. An apparatus for testing moisture permeation from a periphery (or an edge face) of a sheet body having peripheries through the sheet body's internal volume via its surface to the outside, the apparatus characterized by
having
a permeation cell comprising a test piece-loading plate that has an opening in a location away from its peripheries (or edge faces) with the plate partitioning the cell interior into a wet chamber and a dry chamber,
a humidistat gas supply system that supplies humidistat gas at prescribed temperature and relative humidity to the dry chamber,
a dry gas supply system that supplies dry gas to the dry chamber, and
a humidity sensor connected to the dry chamber to detect the gas temperature inside the dry chamber; and
having a constitution in which the sheet body as a test piece is placed on the test piece-loading plate, with the sheet body located where the distance along the sheet body between the sheet body's periphery and the opening of the test piece-loading plate forms a permeation channel of a prescribed length through the internal volume (bulk) of the sheet body, the sheet body facing the wet chamber; a moisture-impermeable layer is placed on top of the sheet body;
and the relative humidity of emission gas released from the dry chamber is detected.

16. An apparatus for measuring moisture permeability in in-plane direction of measurement object based on a modified MOCON method, wherein
for the measurement based on the modified MOCON method, the apparatus has a hollow cell and a partition plate partitioning the hollow cell's interior into a wet chamber and a dry chamber,
with the partition plate
(1) placed with its first face opposing the wet chamber and its second face opposing the dry chamber,
(2) having an opening communicating between the wet chamber and the dry chamber, and
(3) having a constitution that blocks moisture from passing between the wet chamber and the dry chamber; and
the apparatus has a constitution in which a measurement object is placed on the partition plate to cover the opening, with the measurement object being impermeable in its thickness direction, and moisture permeability is measured based on the modified MOCON method.

17. The apparatus according to claim 16, wherein the measurement object is a multi-layer structure comprising a pressure-sensitive adhesive layer and a moisture-impermeable layer, with the pressure-sensitive adhesive layer bonded to the partition plate.

18. An electronic part casing having an encasing member having an opening, and a closing member attached to the encasing member, with the encasing member internally having a low-pressure or inert gas space in which an electronic part is housed, the electronic part casing characterized by the following features:
a sealing member is provided to a location between the closing member and the encasing member where the opening of the encasing member is sealed or provided onto the outside of the closing member,
the sealing member is a sheet body having a periphery, placed between the encasing member and the closing member or placed on the outside of the closing member, with the periphery exposed at least partially to an external space,
the sealing member is essentially moisture-impermeable in the thickness direction of the sheet body, and
the sheet body has a moisture permeability through bulk in in-plane direction of bonding interface of a pressure-sensitive adhesive layer of less than 5×10⁻¹ g/m² per 24-hour measurement period, with the sheet body having an internal volume (bulk) forming a permeation channel that has a prescribed length of 2.5 mm, wherein the moisture permeability is determined based on a modified MOCON method, at a permeation cell temperature of 40° C., with humidistat gas at a temperature of 40° C. and 90% relative humidity supplied to a wet chamber.

19. The electronic part casing according to claim 18, wherein the sealing member is bonded, with a 180° peel strength of 3 N/20 mm or greater, to the encasing member and/or to the closing member.

20. The electronic part casing according to claim 18, wherein the electronic part includes a magnetic disc.
